(19) United States
(12) Patent Application Publication
(10) Pub. No.: US 2017/0212289 A1
(43) Pub. Date: Jul. 27, 2017

(54) HOLOGRAPHIC WINDOWS

(71) Applicants: John David WILTSHIRE, COLCHESTER ESSEX (GB); Jonathan Henry WILTSHIRE, COLCHESTER ESSEX (GB); Trevor RHODES, KNUTSFORD CHESHIRE (GB)

(72) Inventors: John David WILTSHIRE, COLCHESTER ESSEX (GB); Jonathan Henry WILTSHIRE, COLCHESTER ESSEX (GB); Trevor RHODES, KNUTSFORD CHESHIRE (GB)

(73) Assignee: BOWATER SOLAR LIMITED, LONDON (GB)

(21) Appl. No.: 15/328,638

(22) PCT Filed: Jul. 24, 2015
(86) PCT No.: PCT/GB2015/052158

§ 371 Date: Jan. 24, 2017

(30) Foreign Application Priority Data
Jul. 24, 2014 (GB) 1413156.9

(51) Int. Cl. G02B 5/32; G03H 1/02; H02S 20/22; G03H 1/04; G03H 1/00; H01L 31/054; G02B 19/00; G03H 1/22

(52) U.S. Cl. CPC G02B 5/32; G02B 19/0042; G03H 1/0256; G03H 1/0248; G03H 1/22; G03H 1/0402; G03H 1/0005; H01L 31/0547; H02S 20/22; H01L 31/0549; G03H 2270/32; G03H 2001/0439

(57) ABSTRACT

We describe a window assembly comprising: a window pane comprising a glass or plastic sheet; and a layer of holographic recording medium attached to said glass or plastic sheet; wherein said layer of holographic recording medium has recorded within the medium a volume hologram configured to direct light incident onto said glass or plastic sheet to propagate within a thickness of said glass or plastic sheet. In embodiments the volume hologram is fabricated by recording a transmission hologram and shrinking the recorded hologram to convert the transmission hologram to an edge-directing hologram configured to direct light in a direction to be totally internally reflected within the window pane, for example at greater than 40°, 50°, 60°, 70°, 75° or 80° to a normal to the surface of the hologram.

### FIELD OF INVENTION

This invention relates to window assemblies incorporating volume holograms in particular, although not exclusively, for using a window as a photovoltaic collector. The invention also relates to holographic film for use in such windows and to methods for fabricating the volume holograms.

### BACKGROUND TO THE INVENTION

It has been recognised that windows potentially provide a useful area for collecting sunlight and converting this to electricity. For example Polysolar Limited in Cambridge UK provides glass incorporating photovoltaic material, although this has a tinted appearance. WO2013/005745 describes double glazing with a diffraction grating sheet sandwiched between two glass sheets to control the transmittance of infrared rays; a solar cell can be used to collect the diverted radiation. WO2013/003890 apparently discloses a similar structure but without solar cells. In WO'745 the presence of solar cells appears to be secondary and the structure is relatively complex and expensive. Prism Solar Technologies Inc., USA has various patent applications describing solar energy concentrators using holograms in combination with a photovoltaic module or cell, (for example, US2013/0319524; US2013/0160850; and US2013/0128326), but these are not suitable for use with a window assembly. US2009/0199893 (and related US2009/0199900) describes the use of holograms to guide light within a thin film towards a photocell, but in practice it is difficult to achieve efficient guiding of light within such a thin film.

Further background prior art can be found in WO2009/099566; U.S. Pat. No. 5,877,874; U.S. Pat. No. 6,274,860; WO2013/078209; U.S. Pat. No. 5,517,3339; US2012/067402; U.S. Pat. No. 8,040,609; and in “Bandwidth- And Angle-Selective Holographic Films For Solar Energy Applications”, Proc. SPIE 3789, Solar Optical Materials XVI, (11 Oct. 1999) Christo G. Stojanoff; Jochen Schulat; Michael Eich; “New Method For Recording Large-Size Holograms Of The Reflective Type With Adjustable Spectral Characteristics In DCG”, Proc. SPIE 2951, Holographic and Diffractive Techniques, (20 Dec. 1996), Ernst Ulrich Wagemann; Philipp Froening; Christo G. Stojanoff; “Photopolymer Holographic Optical Elements For Application In Solar Energy Concentrators”, Holography—Basic Principles and Contemporary Applications May 29, 2013 Izabela Naydenova, Hoda Akbarl, Colin Dalton, Mohamed Yahya So Mohamed Ilyas, Clinton Pang Tee Wei, Vincent Toal and Suzanne Martin; “Optics For Solar Energy: Holographic Planar Concentrator Increases Solar-Panel Efficiency, Jan. 1, 2008”, Glenn Rosenberg, Raymond K. Kostuk, and Mike Zecchino; “Technical Viability Of Holographic Film On Solar Panels For Optimal Power Generation”, S. N. Singh. Preeti Saw, Rakesh Kumar National Institute of Technology, Jamshedpur, Jharkhand (India) RVS College of Engineering and Technology, Jamshedpur, Jharkhand (India) International Journal of Advances in Engineering & Technology, July 2012 ISSN: 2231-1963217 Vol. 4, Issue 1, pp. 217-225; and “Low-X BIPV Window Enabled By Infrared Mirror Film”, Newill, B.; Wagner, M.; Pendell, T.; Roushia, B.; Holbrook, B.; Weber, P. J.; Moening, J. P.; Hebrink, T.; Strharsky, R. J. Photovoltaic Specialists Conference (PVSC), 2013 IEEE 39^{TH}; PP.0459-0464; and in Serov et al., “Properties of three-dimensional holograms subject to emulsion swelling”, Zh. Tekh. Fiz., vol 47, 2405-2409 (November 1977). Background Prior Art relating to Edge-Lit Holographic Optical Elements can be found in GB2,501,754A and U.S. Pat. No. 6,646,636, as well as in US2003/020975; US2006/126142; US2003/235047; U.S. Pat. No. 5,418,631; U.S. Pat. No. 6,750,996; and R S Nesbitt, “Edge-lit Holography: extending size and colour”, MSc

Thesis M.I.T 1999.

There is therefore a need for improved approaches which are more efficient, cheaper, and easier to use.

### SUMMARY OF THE INVENTION

According to the present invention there is therefore provided a window assembly comprising: a window pane comprising a glass or plastic sheet; and a layer of holographic recording medium attached to said glass or plastic sheet; wherein said layer of holographic recording medium has recorded within the medium a volume hologram configured to direct light incident onto said glass or plastic sheet to propagate within a thickness of said glass or plastic sheet.

In embodiments the use of a volume hologram enables the efficient handling of incoming broadband radiation, in particular sunlight, and the use of the glass or plastic sheet forming the window itself as the propagation medium for the light directed towards the photovoltaic element(s) is practically convenient and efficient and more particularly reduces the angle through which the incident radiation needs to be turned. This latter advantage also leads to a greater range of acceptance angles for the incoming radiation over which incident light can be directed to propagate within the window sheet. The skilled person will recognise that references to propagation within the thickness of the sheet refer to propagation in a predominantly lateral direction within the thickness of the sheet. Unlike thin holograms of the surface relief type, volume holograms, when used in accordance with the Bragg condition, are capable of close to 100% diffraction efficiency at a selected wavelength.

In some preferred embodiments the light propagating within the window pane itself propagates by total internal reflection, in embodiments propagating at least by total internal reflection at a surface of the glass or plastic sheet of the window not bearing the volume hologram. This provides advantage over an arrangement in which, for example, total internal reflection within a holographic film were attempted since this later would need significant refractive index mismatches on both sides of the holographic film so that it would be difficult to make such a system work where the film applied to the glass or plastic sheet of a window. Therefore, in embodiments of the invention, the volume hologram directs the incident light to propagate at an angle to and normal to the glass or plastic window sheet equal to or greater than a critical angle of the glass or plastic sheet. Depending upon the geometry (the path length and number of internal bounces needed) the propagating light may also totally internally reflect off an outer boundary of the volume hologram, that is at a hologram/substrate-air interface. The skilled person will recognise that it is not essential for there to be total internal reflection of the light propagating within the thickness of the window sheet—light may propagate sufficiently close to a plane of the sheet not to need waveguiding, but waveguiding can improve the range of acceptance angles and hence direct more light to the solar cell(s). In embodiments some rays arrive at the solar cell(s) without reflection, more particularly “centre-line” rays, but when the angle of incidence changes TIR is advantageous to enable capture of other incident light. In embodiments therefore the volume hologram comprises an edge-directing hologram configured to direct light in a direction to be totally internally reflected within the window pane, for example at greater than 40°, 50°, 60°, 70°, 75° or 80° to a normal to the surface of the hologram. As described later, in some preferred embodiments such a hologram is fabricated by recording a volume transmission hologram and then shrinking the recorded hologram layer to convert the transmission hologram to an edge-directing hologram.

Since a volume hologram is wavelength-selective, in preferred embodiments the volume hologram is fabricated to direct longer wavelengths, at which greater solar energy is present, towards the photovoltaic element and to transmit shorter wavelengths through the window. Optionally the wavelengths directed towards the photovoltaic element maybe selected to match a peak sensitivity of the PV element. The skilled person will understand that this can be achieved by selecting a fringe spacing within the volume hologram as described later. The skilled person will also recognise that the precise fringe spacing depends upon a combination of wavelength and angle of incidence of light on the fringes—which will in turn generally depend upon the latitude at which the window assembly is employed. Methods to determine fringe and spacing/angle for a particular latitude will be described later. Embodiments of the volume holographic system described here are capable of the efficient re-direction of sunlight from an easterly or westerly aspect and need not face south—for example they work efficiently on the East and West sides of a south-facing building.

In preferred embodiments of the window assembly the volume hologram comprises fringes at a range of different angles such that incident light rays (of a given wavelength) at a range of angles to a normal to the window are directed to propagate substantially parallel to one another through the thickness of the window. Typically the plane of a window defines two orthogonal axis, a vertical direction in which the sun elevation alters and a horizontal direction in which the sun azimuth alters. Preferably, therefore, the volume hologram is arranged to direct light at a range of angles in each of these directions to propagate in substantially the same direction within the thickness of the glass or plastic sheet. Thus the range of acceptance of rays of light by the system may be defined by a rectangular pyramid with a vertex located on the window.

In some embodiments, to enable the assembly to direct light from a range of elevations of the sun above the horizon a fringe angle varies in a vertical direction through the volume hologram, in particular the fringes being tilted more towards the vertical at a shallower angle at the surface at the bottom of the hologram than at the top. Additionally or alternatively, to accept light from a range of lateral, azimuth angles of the sun the hologram may comprise a plurality of sets of fringes (overlapping within the hologram) each to direct light downwards from a particular solar azimuth. This reduces the tendency for the solar radiation to be concentrated at a bottom corner of the window. Although in some preferred embodiments a photovoltaic element or elements is distributed along the bottom edge of the window it is none the less preferable to configure the hologram to direct light vertically downwards for a range of different solar azimuth angles-without such an approach light coming in to either side of the normal will tend to be directed in a diagonally downwards direction towards one or other corner of the window. In embodiments such a volume hologram may comprise a hologram of holograms, more particularly a hologram of a set of holograms, each conveniently having the form of a vertical stripe, each configured to direct incoming light from a different azimuthal direction substantially vertically downwards. In a still further approach additionally or alternatively the volume hologram may comprise a plurality of layers, each having fringes at a different set of angles, each of the layers being indexed by wavelength such that at different angles of incidence (elevation and/or azimuth) different wavelengths of the incident light are directed to propagate substantially parallel to one another. The skilled person will appreciate that a volume hologram can provide this function because the fringes in a volume hologram are both wavelength and angle selective. In a large window pane specific zones of the surface may be used to gather and direct light more efficiently to the PV cells.

The above described techniques address issues of increasing efficiency of collection of sunlight from a range of different vertical and azimuth angles. As previously mentioned, however, volume holograms are also wavelength-selective but it can be desirable to increase a range of wavelengths over which the volume hologram operates. In embodiments this may be achieved by “chirping” the volume hologram such that a spacing of the fringes increases from one lateral surface of the hologram to another—at is from the front to the back surface or from the back to the front surface. This can be achieved by chemical processing, as described later, and facilitates collecting and delivering light to a PV element or elements over a wider range of wavelengths.

In some preferred implementations the layer of holographic recording medium comprises a layer on a film substrate which is glued to the glass or plastic window sheet with the volume hologram sandwiched between the sheet and film substrate to protect the hologram. Preferably the hologram is mounted on an interior rather than exterior surface of the window in order to avoid physical damage to the coated layer or its carrier film (which may be, but is not limited to, PET or TAC film). Importantly index matching glue is employed, in particular to index match one or both of the hologram window sheet and holographic recording medium to better than 0.1, 0.005, or 0.001.

In some arrangements a sandwich configuration may be employed, with glass on both sides of the hologram. Such a configuration may be used, for example, in a vehicle.

Optionally where the volume hologram is supported on a film substrate the substrate itself may be provided with a conventional image, for example by frosting or coating a “rear” surface of the substrate (that is, the surface not bearing the volume hologram). Additionally or alternatively the volume hologram itself may include an image, that is as well as fringes to direct the incoming sunlight, the volume hologram may encode an image which then may be replayed by edge-lighting the window. Such an image may be a three dimensional holographic image. Optionally this may also utilise the incident sunlight to replay, for example utilising wavelengths not involved in the energy gathering system. Additionally or alternatively LED edge lighting may be employed.

The invention also provides holographic film, in particular for the above window assembly, comprising a film substrate bearing a layer of holographic recording medium, wherein said layer of holographic recording medium has recorded within the medium a volume hologram configured to direct light, incident onto the film or onto a glass or plastic sheet to which said film is attached, to propagate within a thickness of said film or said glass or plastic sheet, in particular wherein said volume hologram includes a hologram of an image of a spatial pattern such that said image in reproduced when said volume hologram or glass or plastic sheet is edge lit.

For example, the hologram may comprise a “multi-channel” image. One image can be associated with light gathering, and one or more others with image rendition. Additionally or alternatively a multiple layer coating and/or a double sided coating maybe employed, for example in a silver halide system. Then each individual layer, on either surface of the substrate may be addressable by similar or differing laser wavelengths so as to allow the recording of individual (essentially independent) fringe structures for light harvesting or image construction purposes.

Preferably, but not necessarily, the glass or plastic sheet comprises a (transparent) window pane. Previously described features of the volume hologram may be provided in such a film. Thus, for example, the hologram and/or substrate may include an image to be replayed in the case of an image encoded in the hologram to be replayed by edge-lighting the hologram. In combination with one or more photovoltaic elements such an arrangement may be employed to capture solar energy during the day and to replay the encoded image at night by using the stored energy for edge-illumination (such as LED illumination) of the hologram. In this way large area signage and other illumination/imagery may be provided; a similar system may also be used as a covering layer for a sign or the like. Advantageously, such a layer may include, in at least one layer, a hologram capable of re-directing high energy ultraviolet light away from a substrate surface (often subject to damage or destruction), towards a light collection device a previously described.

In a related aspect the invention provides a method of providing solar power, the method comprising: mounting a layer of holographic recording medium on a window pane comprising a glass or plastic sheet; the method further comprising: recording a volume hologram in said holographic recording medium; directing sunlight falling on said window using said volume hologram to propagate within a thickness of said sheet; and illuminating one or more photovoltaic elements with sunlight escaping from a lateral edge of said window to provide said solar power.

Again, the embodiments of this method may include the previously described features of the window assembly.

It is difficult to manufacture a volume hologram for the above described window assemblies/methods because with a conventional process involving interfering laser beams it is difficult to achieve the desired angle of film fringes within the hologram because of light refraction at the boundaries of the holographic recording medium.

The invention therefore provides a method of fabricating a volume hologram, in particular for the window assembly described above, the method comprising: providing a master volume hologram comprising fringes configured to direct light, incident into said master volume hologram from a range of angles, along substantially the same direction; and contact copying said master volume hologram into holographic recording film in a continuous or stepwise continuous process in which said holographic recording film is carried on a linear or drum-type transparent mechanism.

In embodiments of the method the master hologram is fabricated using a recording process in which the holographic recording medium/film is sandwiched between a pair of transparent (glass or plastic) substrates since such an arrangement allows a wider range of fringe angles to be achieved within the volume hologram because the holographic recording medium is more closely index matched to the transparent substrates than it would be to air. Once the master hologram has been fabricated it may then be contact copied in a continuous or stepwise continuous process using holographic recording film on a linear conveyer or drum.

A master hologram for these purposes may be a volume reflection master hologram, wherein the fringe microstructure is organised, by chemical and physical (i.e. illumination) means, to provide peak reflectivity (diffraction efficiency) at the wavelength(s) of the laser(s) used to transfer the image into the copying film in the mass production process. Where appropriate, such a master may be produced so as to include a plurality of fringe structures, each with a specific peak reflectivity.

With respect to the method of copying the master hologram into the film by virtue of a said drum replication system in embodiments, the use of a metallic surface relief hologram (such as those used in the embossed hologram production process practiced by specialists such as Opsec Ltd., Washington, Tyne & Wear NE38 0AD, UK) is a useful alternative to the use of a volume reflection master. In this case, multiple laser beams at a wide range of frequencies can be reflected by such a master hologram simply by adjustment of the angle of incidence of the laser light. The skilled person will recognise this as a convenient means to incorporate multiple fringe structures into a hologram. Advantages include: providing a useful means of adjustment of the spectral bandwidth of the mass-produced hologram; the ability to introduce angular variations into multiple independent diffractive microstructures in order to assist the collection of a wider range of rays of incident light; the ability to differentially redirect such light so as to enhance or improve its conversion to electrical energy.

Optionally a fringe angle of either the master volume hologram or the film recording into which the hologram is copied may be rotated after fabrication/copying by swelling or contracting the master hologram or recording film. This facilitates achieving a desired fringe angle. In the case of a reflection volume master hologram, the final fringe spacing should be controlled to provide compatibility with the copying laser wavelength, which may differ from that of the laser used for creation of the master.

The master hologram may be fabricated to allow for a range of angles of incident light, for example a range of solar elevations, by (unconventionally) interfering a first laser beam comprising substantially collimated light with a second laser beam in which the light is diverging. This produces fringes at a range of different angles across the hologram so that different (lateral) portions of the hologram can be used to direct light through the thickness of the window glass or plastic when the light is incident at different at different angles. Although it is convenient to employ one diverging laser beam and one collimated laser beam in principle a pair of diverging beams, or one diverging and one converging beam could be employed to achieve similar results.

Additionally or alternatively the master hologram may be configured to direct light down through the window when incident over a second range of angles, for example orthogonal to the first range of angles, for example an azimuthal sun direction. This can be achieved by recording a plurality of first holograms each formed by interfering a pair of laser beams at a different respective angle, and then replaying the plurality of first holograms and recording a hologram of the replayed result to fabricate the master hologram. Conveniently the first holograms may comprise stripes on a common holographic emulsion. The stripes may then be simultaneously illuminated to replay a combination of the holograms for recording in to the master hologram.

The inventors have also recognised further techniques which may be employed to fabricate fringes of the desired/target angle/spacing.

Thus according to a further aspect the invention provides a method of fabricating a volume hologram, in particular for the window assembly described above, the method comprising: interfering first and second laser beams; and recording a pattern of said interference in a holographic record medium, said pattern comprising a set of generally parallel fringes having a fringe spacing and a fringe angle relative to a surface of said holographic recording medium; the method further comprising: tilting said holographic recording medium at a tilt angle relative to said beams during said recording such that said recorded fringes have a first said fringe angle; and changing a thickness of said holographic recording medium after said recording to rotate said fringes relative to said surface of said holographic recording medium, in particular to convert the recorded hologram from a transmission hologram to an edge-directing hologram.

Broadly speaking in embodiments of the method a target fringe angle is achieved by recording interfering laser beams while the holographic recording medium is tilted so that the resulting fringes are also tilted, and then rotating the tilt angle to achieve the target fringe angle by swelling or contracting the holographic recording medium after exposure. The skilled person will know that there are many chemical techniques which may be employed to add in (swell) or wash out (contract) material from a holographic recording medium, some using a hardener to lock in the thickness change. Example hardeners are glutyraldehyde or formaldehyde optionally in combination with a second (catalyst) hardener such as resorcyl aldehyde. Still other techniques pre-swell the holographic recording medium so that it contracts after the hologram has been recorded. These techniques maybe employed to change a wavelength at which a hologram operates but in embodiments of the invention they are employed to provide a controlled fringe rotation to achieve a target fringe angle within the volume hologram.

Such a swelling medium/procedure may include real-time absorption of water or other aqueous or organic fluid which has the effect of expanding a gelatin layer containing silver halide, or in a photopolymer medium may for example comprise an organic solvent capable of expanding the recording layer medium. There is also an opportunity to expand the gelatin layer of a silver halide emulsion by the application of adhesive laminates which may contain solvent or aqueous content capable of migrating into the active recording layer after conventional chemical processing, so as to increase the bulk of the layer with the effect of increasing the fringe spacing in the hologram such that longer wavelengths of light are reflected. Conversely in the case of photopolymer such as Bayfol HX from Bayer Materials Science the peak wavelength of diffracted light can be reduced by the application of adhesive laminates which act as an absorbent sink to components of the finished hologram, with the effect that the contraction of the layer results in the formation of a grating of higher frequency.

In some preferred embodiments of the method the recording directs one or both of the interfering first and second laser beams onto the holographic recording medium through a liquid or solid material which displaces air from the interface of the recording layer. Preferably the liquid acts as an index matching or surface coupling medium so that the solid component such as a glass lens or prism is effectively in optical contact with the holographic recording medium or coupled to the holographic recording. This helps to achieve a relatively shallow angle of the fringes to the surface of the recording medium (film), which is useful for a volume hologram for a window assembly as described above.

In some embodiments, particularly suited to mass production, the holographic recording is made by moving the holographic recording medium past the interfering, preferably by passing the holographic recording medium over a drum. In preferred implementations one or preferably both of the beams are provided to the holographic recording medium via a solid optical element, such as a lens, block or prism, of refractive index greater than 1.3, for example of glass or plastic. This assists in achieving the desired fringe angles within the recording medium. Preferably the solid optical element is optically coupled to the recording medium via a liquid layer, to avoid a potential air gap. In some particularly preferred implementations the liquid also acts to swell the recording medium, or to maintain the recording medium in a swollen state. The liquid may then evaporate at some later stage to reduce the thickness of the recording medium and rotate the fringes. In embodiments the liquid may be delivered by a roller arranged to apply the liquid to the film before the region of interfering beams is reached. Depending on the recording medium, the liquid may be a polar or non-polar, organic or inorganic or aqueous solvent; in embodiments the liquid may comprise or consist essentially of water.

In a still further aspect the invention provides a method of recording a volume of hologram in a band of holographic film, the method comprising: passing said film over a rotating drum; illuminating a region of said film on said drum with a first laser beam; illuminating said region of said film with a second laser beam to create optical interference in said region; recording a pattern of said interference in said film.

Embodiments of this technique recognise, especially, that it is advantageous to produce the target final fringe structure in the mass production process in the most convenient and technically simple way in the interests of the cost and speed of production of the final product. For example, in the event that one requires an efficient means to create a simple microstructure such as a plane grating featuring fringes tilted with respect to surface of the film at 20° or 30° or the like to the surface of the film, one can arrange for laser beams to be incident on both sides of the film to directly produce a reflection hologram whose fringes lie at a shallow angle to the surface of the film. Alternatively, the technique may arrange for a single laser beam, spread in one dimension in the form of a scan line or spread in two dimensions in the form of a collimated or divergent (for example circular) beam, to be incident upon a film layer at a specific angle such that it is reflected from a master hologram or other retro-reflective surface. Such an approach can be applied to a rotary ‘drum’ or to a step and repeat replicator system.

In embodiments the illuminated region on the cylindrical drum may take the form of a line on the surface of the cylinder running generally parallel to the axis of rotation. In embodiments a mirror, prism or other beam deflector may be located within the rotating (in embodiments transparent, e.g. glass) drum to direct light from the first laser beam outwards along the radial direction (perpendicular to the axis of rotation of the drum) and the second laser beam may be directed to intersect the first at the surface of the drum bearing the holographic film, in embodiments at a glancing angle, or close to tangentially, to the film. In embodiments the illuminated region of the film in which the hologram is recorded may be located in a liquid bath, for example comprising water or an organic solvent. This can assist with index matching or surface coupling and hence achieving the desired fringe angle within the holographic film and/or may be used to swell (or contract) the film where the hologram is recorded so that the fringe spacing and/or angle may afterwards be modified by contracting (or swelling) film after recording, preferably back to its original thickness or thereabouts.

An index matching or surface coupling fluid may be used in order to achieve the desired angle of incidence (for “shallow” fringes lying close to the film surface). This approach facilitates the entry of oblique rays of light into a medium of greater refractive index. For example the inclusion of a fluid such as methanol or propan-2-ol facilitates introducing one or more beams into the film at more oblique angle. Such volatile liquids (and also water), particularly if used in the form of a capillary-thin layer, may readily be evaporated and/or recovered in order to facilitate movement of the dry film to the next stage in the production process.

In the case of an aqueous reservoir providing expansion of a gelatin (or other water absorbing) layer in addition to the surface optical coupling previously described, a gelatin photosensitive layer will typically expand to approximately four times the thickness of the dry film. This has the effect that the recorded fringe microstructure may be recorded as a transmission volume hologram, wherein the fringe structure in accordance with Bragg's Law, is a function of the angle dividing the incident beams. Conveniently, the subsequent contraction of the recording layer results, in this embodiment of the technique, in a rotation of the fringe angle in the layer and an increase in frequency of the fringes, such that light of the desired wavelength is reflected by the modified microstructure in the desired direction with respect to the plane of the film.

As previously described the film may be illuminated via a solid optical element and, preferably, a liquid to optically couple the laser beams into said film. In embodiments the liquid is chosen to swell the film prior to recording and is preferably afterwards removed from (allowed to leave) the film, for example by evaporation. The liquid (examples of which are given elsewhere herein) may be deposited onto the film prior to the illuminated region (in a direction of travel of the film around the drum), for example by a roller on or adjacent said film.

In a related aspect the invention provides apparatus for recording a volume hologram, in particular for the window assembly described above, the apparatus comprising: a rotating drum arranged to carry a band of holographic recording medium; at least one source of coherent light arranged to create an interference pattern on an illuminated region of the drum; a solid optical element to optically couple interfering beams of coherent light from said at least one source into said holographic recording medium.

In some preferred embodiments the apparatus further comprises a roller to apply a liquid to the holographic recording medium on the drum prior to the illuminated region, for index matching and/or to swell the recording medium.

The invention still further provides a method of fabricating a volume hologram, in particular for the window assembly described above, the method comprising: recording said volume hologram as a transmission hologram; and shrinking the recorded hologram to convert said transmission hologram to an edge-directing hologram configured to direct light in a direction at less than 45°, 30° or 15° to a surface of the hologram.

Such an approach is particularly suited to mass production: the transmission hologram may be fabricated by shining interfering laser beams onto the same side of a holographic recording medium, for example a band of film on a linear conveyor or wrapped partly around a rotating drum. The recorded transmission hologram may then be converted to an edge-directing hologram with fringes at angles to direct diffracted light to propagate laterally within the film and/or within a window pane to which the film will be attached. This may be achieved by shrinking the thickness of the recorded hologram (recorded holographic medium), for example by removing material from the recorded holographic medium such as water-soluble material and/or silver or a silver compound.

The skilled person will recognise that the use of the ‘transmission hologram’ format at exposure stage allows the fringe frequency to be selected (in accordance with Bragg's Law) by a combination of the wavelength of the laser light used for exposure of the film, the angle between the beams of light incident upon the film, and the conditions of gelatin emulsion shrinkage or expansion introduced by the processing chemistry or the emulsion formulation.

The B.A. thesis University of Vermont, by Julie L. Walker “In situ color control for reflection holography” details example methods of mixing aqueous solutions of solvent in order to provide linear expansion of Agfa Holotest film with respect to time in the bath. This technique can provide controlled expansion of the recording layer additionally or alternatively to other techniques described herein such as the inclusion of water soluble bulking agents to the emulsion layer at the coating stage (which can result in overall shrinkage of the processed film of the order of up to 30% or 40% or 50%). Together with or separately from immersion in, for example, water, these techniques can result in gelatin emulsion expansion of the order of multiples of four or five times the original coated layer thickness (dependent, inter alia, upon the range of hardness levels applied to emulsion coating process).

### BRIEF DESCRIPTION OF THE DRAWINGS

These and other aspects of the invention will now be further described, by way of example only, with reference to the accompanying figures in which:

FIG. 1a to 1e show a window assembly according to an embodiment of the invention;

FIG. 2 shows a first example of a hologram recording process for fabricating a volume hologram for use with the window assembly of FIG. 1, according to an aspect of the invention;

FIGS. 3a to 3d illustrate techniques for the fabrication of a volume hologram for the window assembly of FIG. 1 for handling a range of vertical and lateral (solar elevation and azimuth) angles of incident light;

FIGS. 4a to 4c illustrate a contact-copying based volume hologram fabrication process according to an aspect of the invention, and a drum-based volume hologram fabrication process according to an aspect of the invention;

FIGS. 5a to 5e show schematic illustrations of volume holograms for diffracting light at multiple different wavelengths, in embodiments of which fringe angle is indexed by wavelength;

FIG. 6 illustrates an example chirped volume hologram for use with embodiments of the invention;

FIGS. 7a to 7e illustrate, schematically, techniques for fringe rotation and for hologram fabrication for use in embodiments of aspects of the invention;

FIGS. 8a and 8b illustrate example target fringe angle and spacing requirements;

FIGS. 9a to 9e illustrate details of an example fringe rotation/spacing modification process according to embodiments of the invention;

FIGS. 10a and 10b illustrate incorporation of a replayed holographic image into a volume hologram for use in embodiments of the invention; and

FIG. 11 illustrates holographic recording film storing a volume hologram according to an embodiment of the invention and an additional image defined by the film substrate.

### DETAILED DESCRIPTION OF PREFERRED EMBODIMENTS

Broadly speaking we will describe a system which employs a volume holographic grating mounted in contact with the surface of a glass plate, more particularly a window, using an index-matched adhesive bonding agent. The fringes of the volume holographic grating are arranged to diffract light incident upon the surface of the glass, preferably sunlight having a particular range of wavelengths, into the thickness of the plate. Preferably within the plate the direction of propagation of the diffracted light is such that a majority of the light exceeds the critical angle for a glass/air interface such that the diffracted light is totally internally reflected at one or both faces of the glass plate. Therefore the diffracted light continues within the thickness of the glass plate until it arrives at an edge of the plate where it is incident upon a linear array of photovoltaic cells, preferably arranged to capture substantially all of the light exiting the plate in this manner, for production of electrical energy.

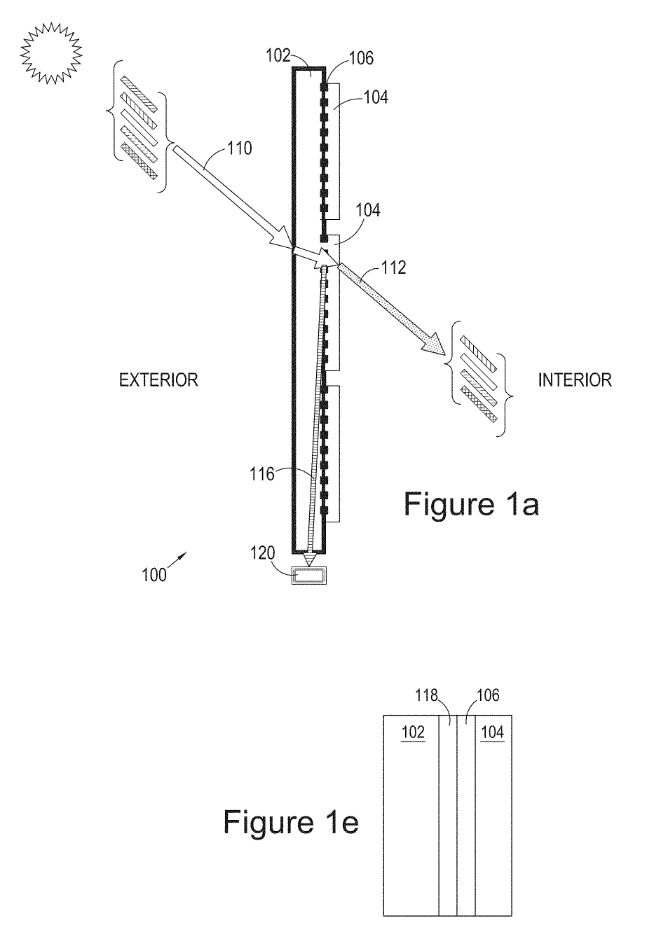

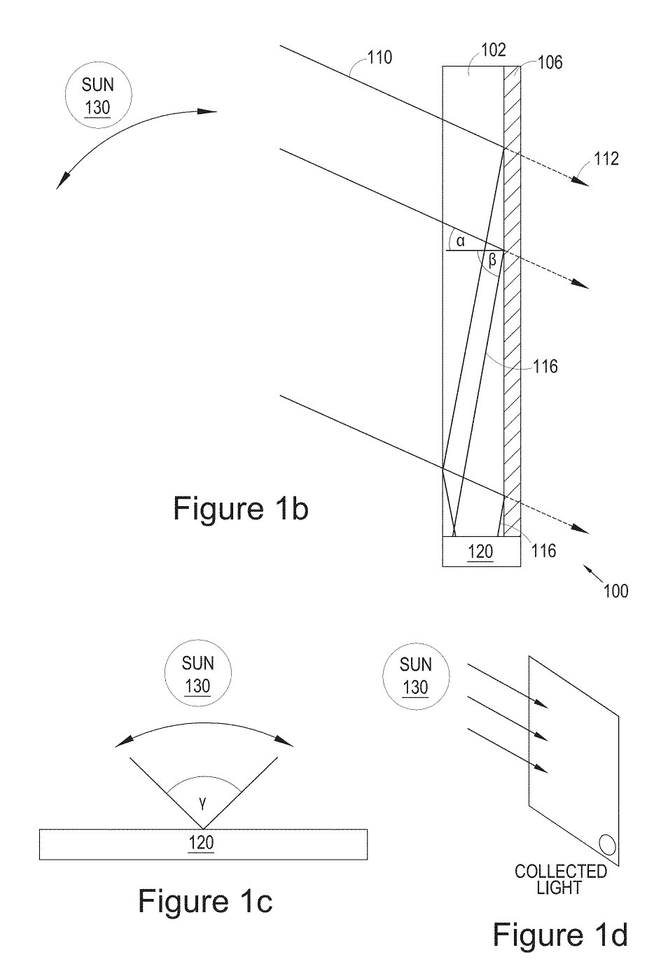

FIG. 1a shows, schematically, a window assembly 100 of this type comprising a glass window an internal surface of which is provided with a layer of holographic film or, as illustrated, one or more volume hologram tiles 104 bearing one or more volume holograms, schematically illustrated as fringes within a layer of holographic recording medium 106. Incident sunlight 110 is transmitted through window 102 and the holographic film/tiles 104 to provide an exit beam 112 parallel to but slightly displaced from beam 110. A proportion of the incoming beam 110 is diffracted by the holographic layer 106 to provide a beam 116 which propagates within the thickness of the window 102 down towards one or more linear photovoltaic elements 120 such as a PV array. In some preferred embodiments the diffracted beam 116 comprises a relatively longer wavelength portion of incoming beam 110 as this is where both the majority of the solar energy is located and also where PV cells tend to be most efficient. Thus beam 112 exiting the interior surface of the window will tend to have a slightly “cooler” colour than beam 110.

Thus in broad terms providing a volume hologram with a suitable holographic grating can be fabricated red and infra-red components of sunlight can be exploited to generate significant PV power with very little effect on the overall function and appearance of the window. Thus, for example, the arrangement could be provided on a glass window of a south facing exterior wall of a building to receive sunlight which is at an angle of incidence which is a function of the latitude of the site. Red and infrared components of the sunlight are “reflected” from the holographic mirror grating at an obtuse angle down into the glass pane such that the light is totally internally reflected and arrives at the lower edge of the pane. At this lower edge light is incident upon the glass/air interface at a small angle (to the normal) and thus there is low internal reflection and around 95% of light can exit to fall upon the surface of the photovoltaic cell(s). In more detail sunlight incident at a range of angles around a central, design angle, and having a relatively narrow bandwidth around a particular wavelength, is directed along a first order diffraction direction of the volume hologram. This direction is the same direction as a ray would have if reflected by one of the fringes and they may therefore be considered as a “reflection” from the fringes of the volume hologram. Although we refer to a grating, in the embodiments we describe later the fringes do not form a simple grating and have a more complex structure—but it is helpful to consider this simplification for an initial understanding of the basic principles. The light propagating through the thickness of the glass pane is totally internally reflected at the front (exterior) surface of the window and at the interior surface to which the holographic film is attached with an index-matching UV-cured adhesive. The direction of diffracted (“reflected”) light is selected to achieve this total internal reflection, that is, so that if the does meet the interior surface of the glass pane it is reflected at the surface. The situation is slightly more complex for the red/infrared light grazing the interior surface of the window: in this case the volume hologram will not in general act as a mirror for such a ray (because of the angle of incidence) and instead the ray is totally internally reflected from the outer surface of the substrate of the volume hologram, for example at the film/air interface where holographic film is employed.

As will be appreciated from the forgoing discussion, the arrangement of FIG. 1a is a simplification of the system and we will describe further features of a practical arrangement later. However it is also useful for understanding the invention to describe some features of holographic recording media.

A typical hologram comprises a glass plate or film coated on the reverse side with a photosensitive recording layer. In the case of a volume hologram for embodiments of the invention the recording layer has a typical thickness of 4-20 microns (although it can be greater) and within this layer an interference pattern can be recorded which takes the form of a microstructure comprising modulation of the composition and hence refractive index of the layer. In a volume hologram the fringes defined by these modulations occupy the thickness of the layer rather than merely being defined as a surface pattern and thus volume (or “thick”) holograms typically have a thickness of at least 5 times, 7 times, or 10 times the wavelength, which may be the wavelength at which the hologram was recorded or a wavelength at which the hologram reflects. The presence of multiple fringes within the thickness of the hologram means that a volume hologram is relatively wavelength-specific; volume holograms can also provide a high diffraction efficiency, as previously described.

In the case of a silver halide recording medium such as Harman Holo FX™ from Harman Technologies Limited Mobberley, Cheshire UK, typically after exposing a high resolution recording plate or film to a standing wave of interference produced by coherent laser light the film is developed to create black silver metal. Typically this defines a network of ultrafine grains or filaments of silver defining granular planes of metallic silver resembling under a microscope the pages of a book. This provides an amplitude hologram which is inefficient as light is blocked and thus further chemical processing is employed to convert this to a phase hologram for example using a bleaching process. Thus a bleaching solution may be employed to convert the black silver metal in the (typically) gelatin emulsion layer back into silver bromide (refractive index 2.25 in red light). In general during this conversion process reagents may also be employed to encourage microscopic “diffusion transfer” of silver bromide into zones already rich in silver bromide. However, we control this process in moderation, since the existing of large crystals of silver bromide may be regarded as scattering centres, especially with respect to their interaction with light of shorter (blue/ultraviolet) wavelength. The overall chemical changes have the effect of both increasing the index modulation and rendering the film transparent to provide an efficient “phase” grating. Although very orderly planar fringes maybe be created, in embodiments of the invention the fringe patterns are more complex and are controlled to adapt to multiple angles of incidence to control the reflection to adapt the bandwidth and, potentially, even to include effects such as magnification. Apart from this flexibility one of the advantages of employing a volume hologram is that (for a narrow band of wavelengths) one can achieve very high diffraction efficiency corresponding, effectively to a reflectivity approaching 100%.

There are also processing techniques termed SHSG “silver halide sensitized gelatin” wherein the silver content is removed in its entirety and hardening techniques are used to preserve voids in the hardened gelatin, which provide sufficient index modulation in the layer to produce relatively high diffraction efficiency. The removal and recovery of the silver content has a cost saving and environmental advantages.

The skilled person will know that a volume hologram can also be fabricated in a photopolymer material, for example Bayfol HX™, from Bayer Material Science, Chem Park, Leverkusen, Germany. Photopolymer volume recording materials are typically an order or magnitude (or more) less sensitive to light than silver halide recording materials but this can be compensated for by employing more powerful lasers—for example some embodiments of the invention described later employed a 660 nanometre diode pumped solid-state laser (a Flamenco laser from Colbolt Lasers, Sonia, Sweden). This wavelength broadly corresponds to the sensitive range of a silicon wafer photovoltaic cell, which is predominantly receptive to light in the longer wavelength part of the visible spectrum and is therefore convenient for embodiments of the invention. Photopolymers typically do not require chemical processing after exposure to laser light. Instead the holographic grating is formed in real time as a result of migration of species within the coated layer during the polymerisation process creating regions of relatively higher and lower density (refractive index); afterwards ultraviolet light is applied to cure the film and inhibit further monomer activity. Photopolymer material is also able to produce gratings with a diffraction efficiency close to 100% over a band of wavelengths. For both polymer and silver halide films the volume hologram itself is typically very low in colour content, scatter and optical density and thus in embodiments can appear almost invisible.

Referring now to FIG. 1b, this shows a more detailed version of FIG. 1a, in which like elements to those of FIG. 1a are indicated by like reference numerals. Thus an incident beam 110 from the sun 130 at angle α to a normal to the window 102 is directed downwards through the thickness of window 102 at angle β to a normal by hologram 106, as indicated by ray 116, towards PV element 120. The rays 110 from the sun are parallel, as are the diffracted rays 116 travelling within the thickness of the window. Depending upon how shallow an angle rays 116 make with a surface of window 102 (i.e. on how close angle β is to 90 degrees), as well as on the distance of travel, a ray 116 may or may not totally internally reflect off a front (sun-facing) or rear surface of window 102. For a typical window height of order 1 metre it is useful but not essential that rays 116 are able to totally internally reflect off the internal front surface of window 102.

Hologram 106 is a volume hologram and may be considered to be a volume reflection hologram (although for reasons described later neither of the terms reflection hologram and transmission hologram is strictly appropriate). FIG. 1b illustrates the diffracted rays; preferably longer wavelengths are diffracted and shorter wavelengths are transmitted. Thus rays 116 may have a centre wavelength dependant on the fringe spacing of hologram 106, for example of around 600 nanometres. The position of sun 130 relative to the window moves—the sun moves in both elevation and azimuth. In a simple embodiment the diffraction of rays 116 at angle β is optimised for a particular direction of the sun, for example the direction of the sun at noon. However in some preferred embodiments light is diffracted at substantially the same angle β for a range of different solar elevation angles α. Similarly in preferred embodiments rays 116 are directed in substantially the same direction, in particular vertically downwards, for a range of different solar azimuth angles γ, as schematically illustrated in FIG. 1c. If this were not done the solar energy would tend to accumulate in one or other lower corner of the window as schematically illustrated in FIG. 1d. The range of angles over which light is diffracted in substantially the same direction maybe a continuous range or a range of discrete angles as explained below.

In embodiments the volume hologram 106 on film or tile substrate at 104 is attached to window 102 by refractive index matching glue 118, as illustrated in FIG. 1e.

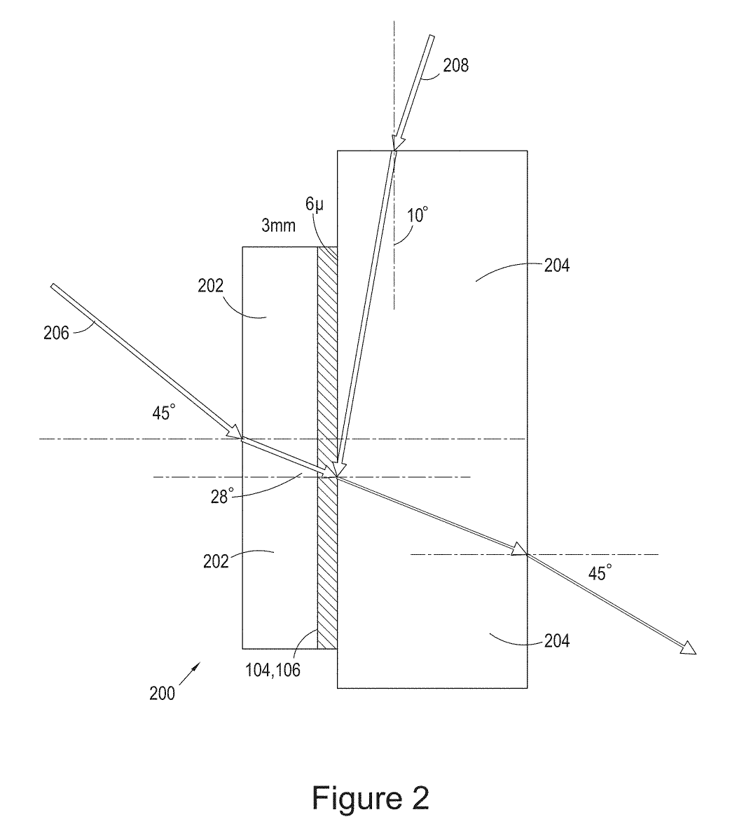

Referring now to FIG. 2, this shows an embodiment, of a first optical apparatus 200 which may be employed to record a volume hologram for the window assembly of FIG. 1. One difficulty with fabricating a volume hologram with fringes at the correct angles is that because the fringes lie at a relatively shallow angle to the surface of the hologram (they lie “flat” within the hologram) it is difficult to provide interfering laser beams at the correct angles because refraction at the boundary of the hologram limits the range of internal angles of propagation of the laser beams; even with a beam which has a grazing incidence on the front surface of the hologram the direction of travel of the beam within the hologram may not be sufficient to give a shallow enough angle to the fringes within the hologram. Thus in the arrangement of FIG. 2 the hologram is sandwiched between a pair of transparent, for example glass substrates or blocks 202, 204 optically coupled to the hologram with index matching fluid (not shown). One of the beams, for example beam 206, enters through the front face of one of the blocks/substrates; the other beam, for example beam 208, enters through the edge of the second glass block/substrate. This enables fringes to be formed at a very shallow angle to the surface of the hologram. In preferred embodiments the refractive indices of blocks 202, 204 are close that of the hologram 106 (which is generally provided on its substrate 104), for example matched to the holographic recording medium to within a refractive index value of better than 0.02. The particular angles of the laser beams are chosen so that after refraction by the glass blocks 202, 204 the beams are travelling in the right direction within the holographic recording medium 106 to generate fringes of the desired angle, in particular to direct rays 116 at the desired angle for the target solar elevation. The skilled person will appreciate that determining the angles of the rays within holographic recording medium 106 is a routine application of Snell's Law, and that the fringe direction in the mirror assembly of FIG. 1 is, in preferred embodiments, a direction in which the normal to the fringes bisects the angle between rays 110 and 116 (that is bisects α+β).

In one embodiment of apparatus for mass producing a volume hologram for the assembly of FIG. 1 an edge-illuminated glass block 204 is provided beneath a film transport system which receives illumination with coherent light from above, the system also including an exposure gate for the illumination. In embodiments a single laser with a split beam maybe employed, for example a 500 mw Flamenco laser operating at 659 nanometres as previously mentioned. Optionally a tuneable laser or multiple lasers of different wavelengths maybe employed to provide simultaneous or consecutive exposure to multiple different colours of interfering beams to increase the spectral bandwidth of the resulting holograph.

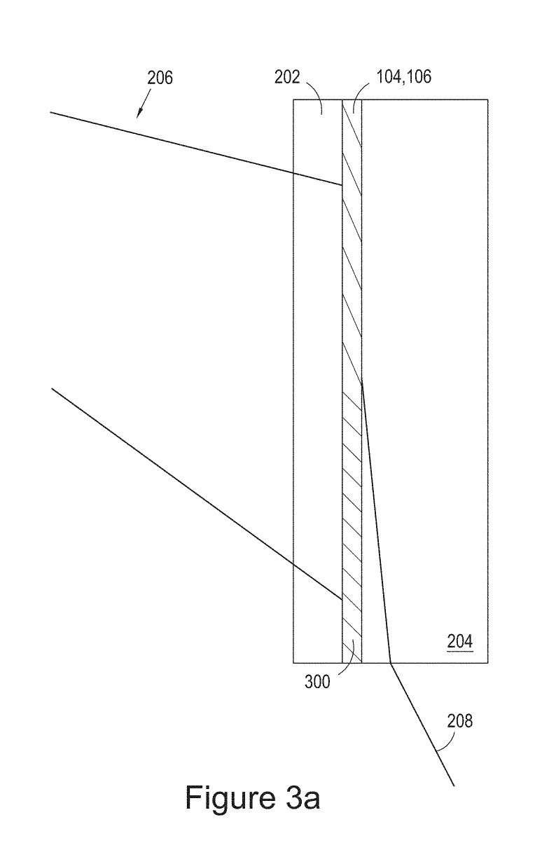

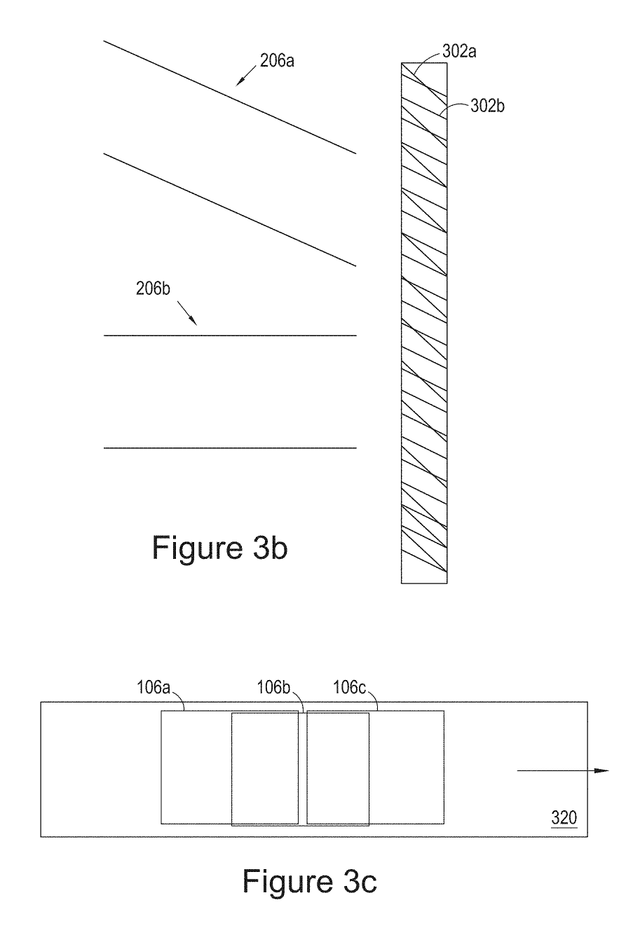

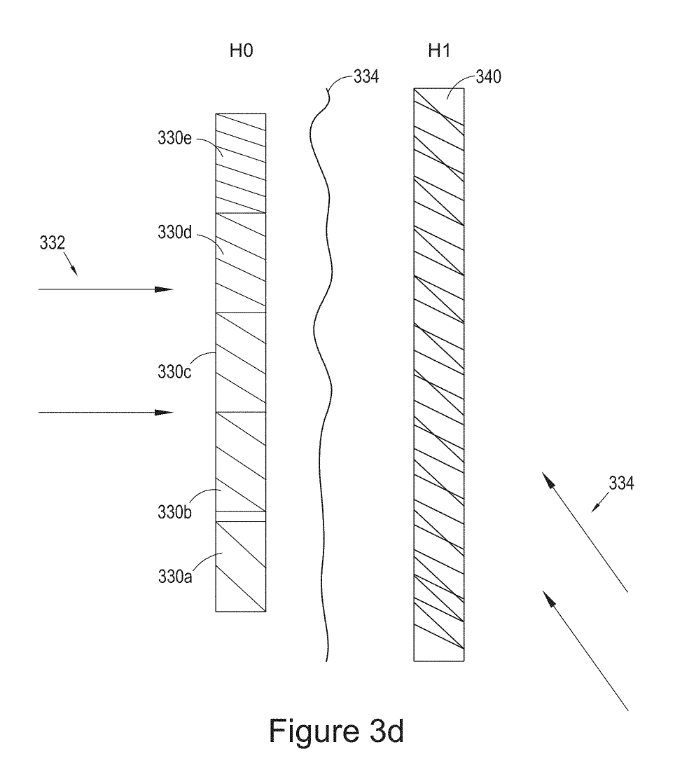

Referring to FIG. 3a, this shows an arrangement similar to that of FIG. 2 but in which one or both of beams 206 and 208 is slightly diverging rather than collimated. This results in fringes which are tilted differently at different lateral locations within the hologram. This enables the volume hologram/window assembly to operate effectively over a range of solar elevations. In the illustrated example the fringes 300 are tilted more towards the vertical (at a shallower angle to the surface of the hologram) at the bottom than at the top of the hologram (when installed) but this is not essential.

An alternative approach is shown, schematically, in FIG. 3b in which multiple exposures with collimated beams 206a, b at different angles are made to produce corresponding sets of fringes 302a, b at different angles within the hologram. FIG. 3c illustrates, schematically, how this can be achieved in a mass production system, in which a film or tile conveyer at 320 moves the holographic recording medium stepwise between positions 106a, b, c at which successive, spaciously overlapping exposures of the film are made. For example for a hologram with a “repeat length” of 1 metre (to match a target window size) exposures may be taken, say every 10 cm. This effectively angularly multiplexes the holograms stored within the film.

Such an approach may be employed to provide a volume hologram which is adapted to efficiently direct sunlight from a plurality of different (lateral azimuthal) angles onto a photovoltaic element. The skilled person will appreciate, however, that whether a range of azimuthal or elevation angles is covered is merely a matter of orientation of the fabricated volume hologram on the window.

Although we have described an example film publication system which employs a glass block to achieve the desired fringe angles within the hologram, we describe different approaches later, which employ a dimensional change of the hologram rather than a glass block to achieve the desired target fringe angles.

FIG. 3 illustrates an alternative approach which may be employed to fabricate a volume hologram with fringes at a range of different angles in order to deflect light from a range of vertical and/or lateral directions towards a PV element in the window assembly in FIG. 1. Thus in the approach of FIG. 3d a first master hologram, H0 is fabricated having a plurality of different regions 330a-e, for example a plurality of vertical stripes, so that within each region the fringes are substantially parallel to one or another but are at different angles from one region to another.

The H0 master may be fabricated as previously described. This H0 hologram is then illuminated by a further collimated light beam 332 to replay the stored holograms simultaneously to create a replayed wavefront 334 and a further beam 336 is then used to record the combination of holograms together in a second master hologram H1340. This second master hologram thus effectively comprises fringes suitable for directing light from a range of angles towards a PV element in the previously described system. Depending upon the direction from which light beam 336 impinges on hologram H1 the hologram may either be a transmission master (as illustrated) or a reflection master.

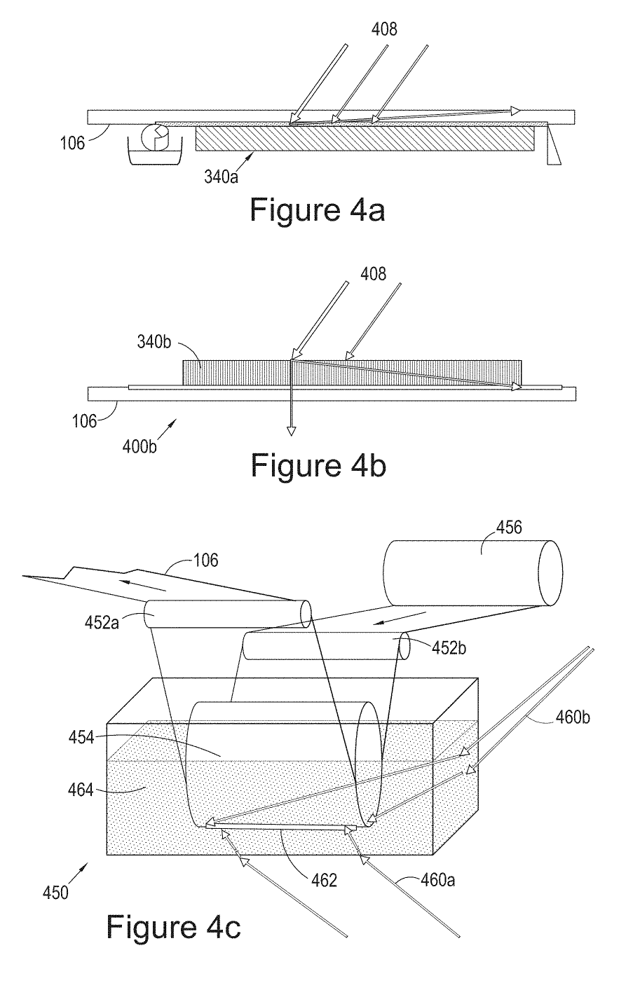

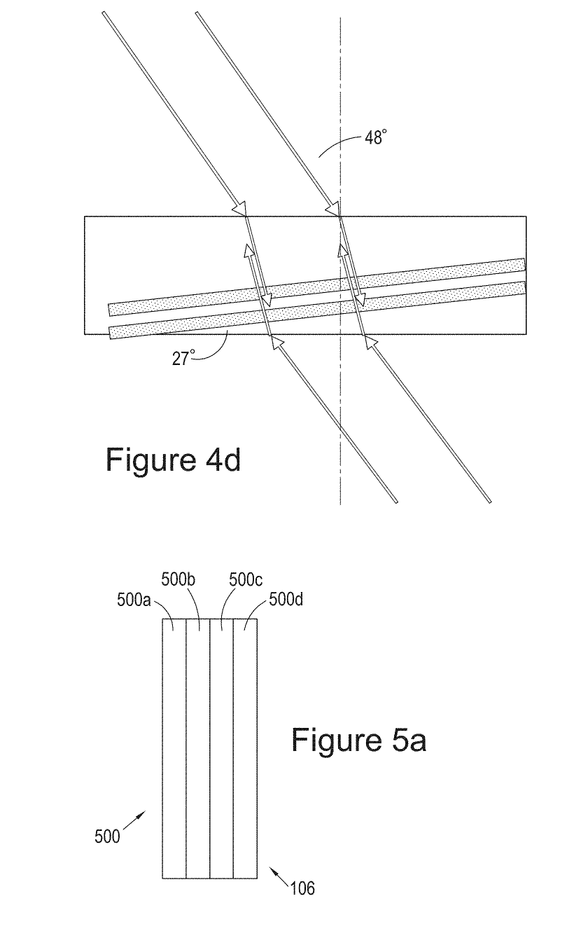

Referring to FIGS. 4a and 4b, these show examples of contact copying systems for 100a, b for copying the H1 master into a holographic recording medium 106 on film or a glass substrate. As illustrated, a transport mechanism, more particularly a hologram drive 402 may include a reservoir 404 of index matching fluid 406 to provide this to the interface between the copied master hologram and the holographic recording medium. (A similar approach may be employed with the previously described arrangement based on that illustrated in FIG. 2). The system of FIG. 4a shows a reflection master hologram 340a; out of FIG. 4b is suitable for a transmission master hologram 340b. In each case the master hologram is replayed to create a wave front which is copied by collimated beam 408 into the joining holographic recording medium 106, suitably index matched.

FIG. 4c illustrates an alternative drum-based hologram recording system 450 in which the holographic recording medium 106 on a film substrate is guided by a transport mechanism 452a,b around a rotating drum 454 where the hologram is recorded and embodiments the recorded film is then captured on a spall 456.

In one embodiment a pair of collimated laser beams 460a,b are overlapped in a region 462 of the recording medium 106 which is within a liquid bath 464 which serves the function of the glass block 204 in FIG. 2. In embodiments one of the beams, beam 460a, is projected into one end of the rotating drum 454, so that it is incident on the recording medium from within the drum. In embodiments this beam defines a plane within which the axis of rotation of the drum lies. Preferably this beam intersects the film at an acute or glancing angle. The second beam 460b may be arranged to intersect the holographic recording medium 106 at an appropriate angle within region 462 in order to achieve the target desired fringe orientation within the film layer.

In another approach the drum 454 may carry a reflection or transmission master hologram 340 as previously described which may be replayed and copied into the recording medium (in which case only a single laser beam is needed). In such an arrangement bath 464 may hold index matching fluid (which is preferable but not essential).

In still further embodiments, which may be combined with either of the previously described approaches, bath 464 may additionally or alternatively hold a liquid to swell or contract the holographic recording medium so that the spacing and rotation of the film fringes may afterwards be adjusted to a desired target angle by contracting/swelling the recorded hologram. This is described in more detail later.

Preferably in a drum-based hologram recording system as shown in FIG. 4c a relatively high powered laser such as a diode-pumped solid state laser is employed to facilitate rapid mass production of the recorded holographic material holographic. An approach which employs post-exposure fringe expansion is particularly advantageous for high speed mass production.

In a further mass production technique which is advantageous in embodiments for the production of simplistic single plane grating elements, FIG. 4d shows an alternative technique where direct exposure to the film is employed without index matching procedures. Here the laser beams of an appropriate wavelength are incident at equal angle in opposite directions upon either side of the film layer. The refraction at the film surface ensures that the grating produced has the correct orientation to produce the desired edge-directing hologram.

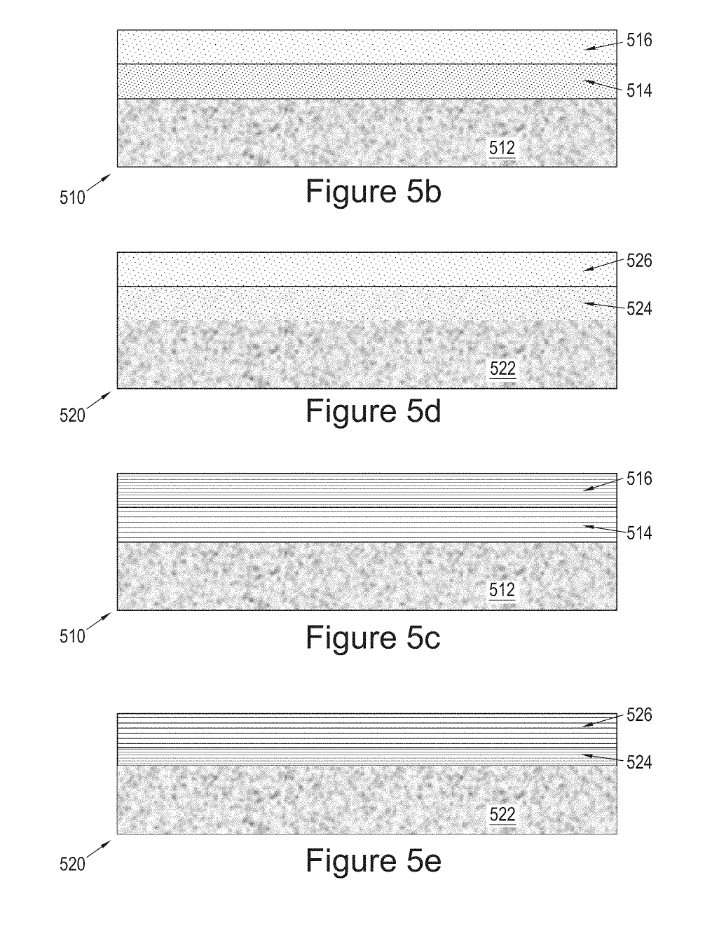

Referring now to FIG. 5a, this shows a further alternative approach which may be employed to fabricate a volume hologram able to direct incoming sunlight at a range of different solar elevation and/or azimuth angles in order to provide actinic light to the PV cell; a similar approach may be used for diffracting selected pairs or groups of wavelengths. In the approach of FIG. 5a a hologram 500 comprises a set of different layers 500a-d each of which is preferentially sensitive to a particular wavelength of light when recording the hologram. In this way different wavelengths of laser light used to record the hologram maybe employed to fabricate sets of fringes at different angles or frequencies within the thickness of the hologram. One advantage of such an approach is that fringes need not overlap within a single layer, which can result in improved diffraction efficiency. (This is particularly useful for a volume hologram as described earlier in which longer wavelengths are preferentially directed towards the PV element since the diffraction of longer wavelengths employs fringes with comparatively greater spacings than the diffraction of visible wavelengths, for example of order 500 nanometres) so that there are typically fewer fringes overall, which allows more precisely defined index modulation.

Suitable recording media are commercially available or maybe fabricated to order, for example by Harman Technologies Ltd. (Ilford Ltd); typically the different layers contain different spectral sensitizers. Additionally or alternatively such recording media may include one or more components in one or more of the layers which enable the layer thickness or density to be controlled in the chemical film processing subsequent to recording. The skilled person will recognise that photographic films are often coated in a plurality of layers, for example to achieve colour recording and we have previously described some particularly advantageous multilayer holographic recording media in US2011/0088050 (hereby incorporated by reference).

FIGS. 5b and 5c show, schematically, a first example multilayer volume hologram recording film 510 before and after recording of a hologram in the film. The film 510 comprises a substrate 512 and a pair of photosensitive layers 514, 516 both sensitive to red light (longer than the first threshold wavelength), but having different peak wavelength sensitivities within the red. Thus, for example, the surface layer 516 may be sensitive to wavelengths in the range 600 nanometres-700 nanometres, and the second layer 514 may be sensitive to wavelengths longer than 700 nanometres, for example comprising a dye or mixture of dyes of the type used in infrared photographic applications for the sensitisation of silver halide. Thus, for example, such a film may be exposed to a first standing wave (interference pattern) at a first wavelength, say 659 nanometres from a Cobolt Flamenco Laser, and a second standing wave (interference pattern) at, say, 1064 nanometres from a Cobolt Rumba Laser. As illustrated schematically in FIG. 5c the 2 layers record separate gratings of different spacing/angle which can thus separately diffract light. Such an approach may be used to increase the bandwidth over which the volume hologram operates and/or to direct light to waveguide within the window when incident upon the window at more than one angle of incidence.

FIGS. 5d and 5e illustrate an alternative approach using a multilayer holographic film which may be employed to achieve a similar result. Thus FIG. 5c shows holographic film 520 comprising a substrate 522 and two subsequent layers 524, 526 which, in this example, both contain the same spectral sensitizer (or correspondingly may both have the same peak spectral sensitivity). However one (or more) of the layers includes a material which may be employed to change a thickness of the layer when the film is developed, for example to reduce the thickness of in the layer in the developed and the dried film. Thus in one example one of layers 524, 526 may comprise gelatin, and the other gelatin in combination with a water soluble polymer (or other material which may dissolved during subsequent chemical processing). In the illustrated example layer 524 includes a soluble polymer so that as shown in FIG. 5e, after chemical processing and drying the thickness of layer 524 is reduced compared with that of layer 526 so that the microstructure of layer 524 has a relatively higher frequency of than of layer 526.

The skilled person will appreciate that the above described approach may readily be generalized to more than two layers.

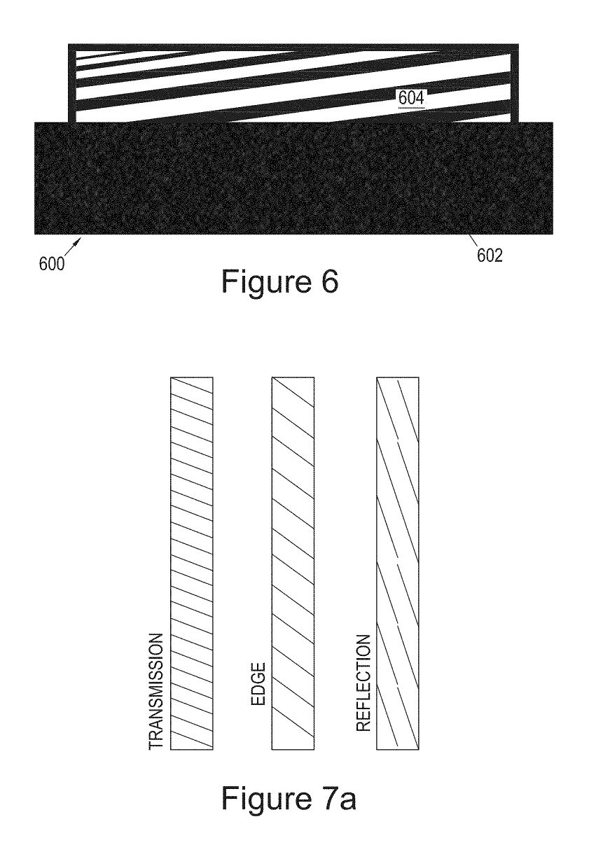

Referring now to FIG. 6, this shows an example of a volume hologram 600 in which the fringes are “chirped” so that the hologram reflects light at an appropriate angle over a wider range of frequencies than would otherwise be the case (albeit at a slightly reduced level of efficiency). Thus hologram 600 comprises a substrate 602 baring a recorded hologram 604 in which the fringe microstructure shows a monotonic increase in the fringe spacing in moving from the front to the rear surface of the recording layer (as shown) or vice versa. This can be achieved by providing a gradual change in the thickness of the emulsion layer during chemical processing of the film; the end result is a chirped fringe frequency (by analogy with radar).

There are various techniques which can be employed to produce such chirping for example the film maybe processed prior to exposure or during or after the developing and bleaching so as to modulate the density of a gelatin layer so that this varies between the front and rear surfaces of the recording layer. For example, rapid processing with a relatively hot developer can act quickly on the surface without diffusing evenly into the depth of the layer as would normally be expected in typical processing technique for photography. This can result in a gradient of silver density in the layer which will then in turn produce a density/refractive index modulation within the layer during the bleaching stage, especially in the event that a solvent bleach is utilised for the purpose. In another approach a pre-swelling step with limited soaking time so as to affect the surface more than the depth of the material may also be employed. In general the forced removal of material(s) from the recording layer under non-equilibrium conditions (for example at excessive levels of activity) results in depth zones within the microstructure shrinking proportionately with respect to their proximity to the surface of the layer. The skilled person will recognise that there are other methods which may also be used to obtain, in effect, different degrees of shrinkage at different shrinkage at different depths within the emulsion layer.

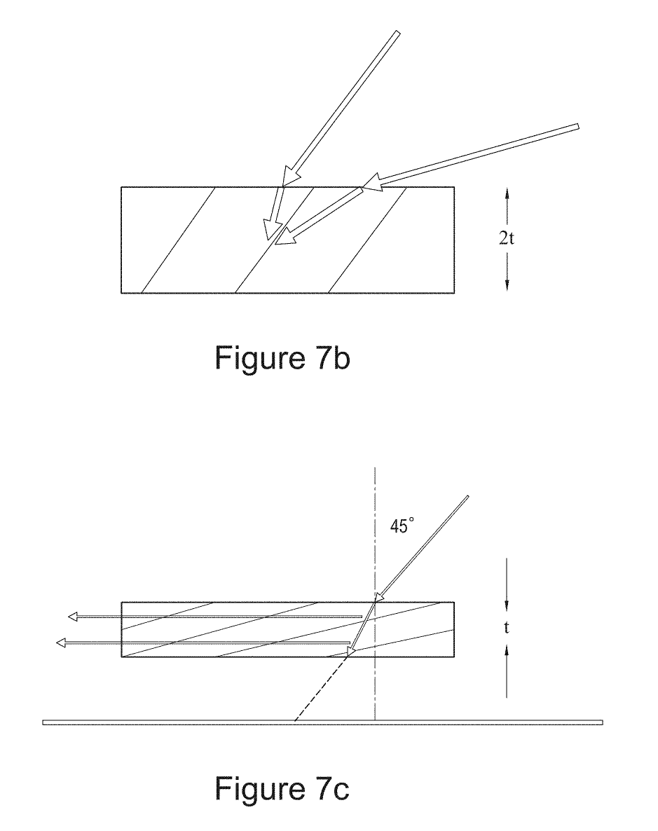

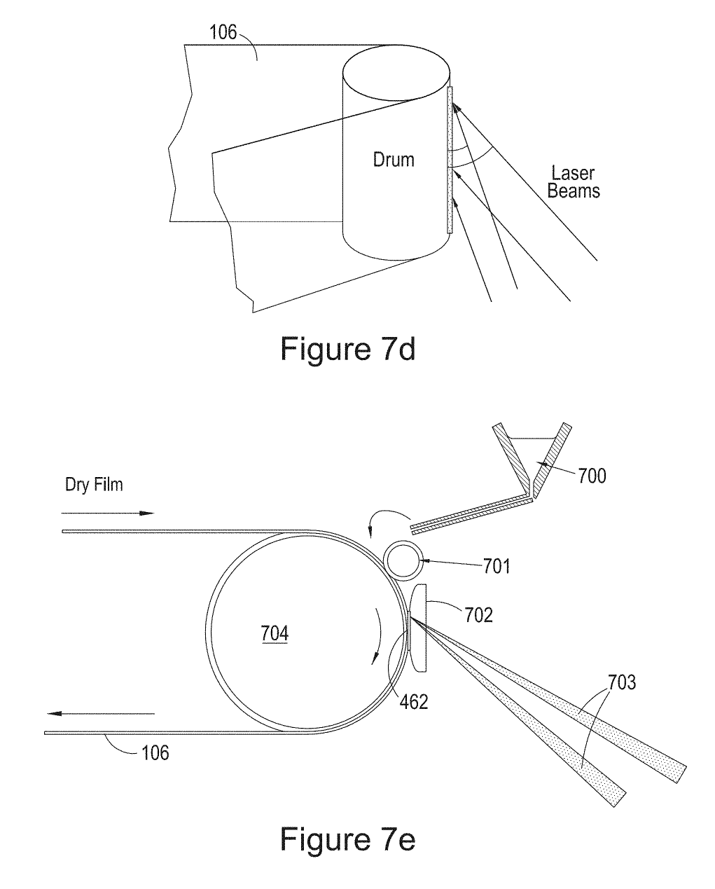

The inventors have also recognised that related techniques may be employed to rotate fringes as well as to change fringe spacing for the volume hologram. This recognition is in part based on the observation that as a volume hologram dries in the laboratory there is a point at which the edge of the holographic plate frequently appears to light up. FIG. 7a illustrates what is believed to occur for certain fringe angles—initially the volume hologram acts as a transmission hologram with fringes lying across the thickness of the film and, as the film dries, the holographic recording medium shrinks and the fringes rotate so that they eventually lie predominantly parallel to the surface of the hologram so that the hologram operates in reflection mode. Between the extremes the fringes pass through a rotation at which light is directed to propagate within the thickness of the film or plate substrate bearing the holographic recording medium. This principle is further illustrated in FIGS. 7b and 7c in which a film of thickness 2t at the time of recording shrinks to thickness t after recording, rotating a fringes so that incoming light is directed to propagate within the thickness of the holographic layer. This approach may be used to rotate the fringes in either direction (and to change our spacing)—for example material may be added into the holographic recording medium and washed out (and hardened) after recording, or the holographic recording medium maybe subjected to a pre-swell treatment for example in a liquid bath, afterwards drying out; or material may be used to swell the recording medium after recording a hologram (subsequently hardening the swollen film). In one example material within the hologram recording layer is soluble in alkaline developer, thus allowing material to be removed from the recording layer so that the thickness of the recording layer is reduced upon drying after bleaching. Suitable film is available, for example Harman Technology Limited, UK. In another example a silver halide/gelatin emulsion layer is exposed whilst wet and hence substantially thicker than usual and post-drying shrinkage is reduced via for example, further post exposure expansion.

These techniques maybe applied in conjunction with or instead of any of those previously described. Broadly speaking they facilitate achieving fringe angles suitable for directing reflected light into the window glass at an angle in excess of the critical angle, to achieve total internal reflection within the window. The skilled person will recognise that expansion and/or contraction techniques to modify fringe spacing may be used in conjunction with various laser line wavelengths such as 514 nm, 532 nm, 561 nm, 594 nm, 639 nm, 659 nm, 694 nm, 1064 nm and so forth.

These techniques are also compatible with high speed mass production in particular, in embodiments a suitable volume hologram maybe fabricated as a transmission hologram with both interfering laser beams incident on the same side of the holographic recording medium. The transmission hologram may then be converted into a (window) edge-Illuminating hologram by shrinking the hologram post exposure. In embodiments such an approach provides further advantages in that the previously described index matching need not be employed. In embodiments, the recording medium need not necessarily be sensitive to infrared (increasing the available range of recording media and avoiding the difficulties of infra-red) and infrared lasers need not be employed to create the interference pattern (which reduces health and safety concerns).

An approach which writes a transmission hologram and then converts this to the desired window-edge Illuminating hologram can be employed with either a linear recording medium transport mechanism of the general type illustrated in FIGS. 4a and 4b or with a drum-based exposure system of the general type illustrated in FIG. 4c (but with the two beams incident present on the same, preferably outer surface of the drum. Again with such an approach there is no need for index matching fluid and the bath 464 is optional depending upon the approach used to shrink the film after exposure. FIG. 7d shows, in outline, a simplified hologram recording apparatus of this general type.

We now consider a geometrical approach to obtaining fringes at a desired target angle for the volume hologram in order to subject diffracted rays within a window on which a hologram is located to total internal reflection. The grating structure maybe positioned on either the outer surface of the window or the inner surface. In the former case the diffracted light passes through the grating before entering the window pane; in the latter case the diffracted light is reflected forwards into the glass. In both cases, however, the geometrical analysis is similar. Broadly speaking embodiments of a volume hologram to diffract light as desired provide an obtuse angle of diffraction, more particularly between 90 degrees and 135 degrees to a normal to the incident ray. Perhaps surprisingly, the configuration of the optical microstructure differs only slightly between these two apparent extremes.

FIG. 7e shows hologram recording apparatus for implementing a method in which dry film 106 is fed onto rotating drum 704. Index matching is facilitated by a carefully controlled capillary supply of, for example, a volatile solvent 700. This facilitates the entry of light into the recording medium at extremely acute (oblique) angles. Example volatile liquid which may be employed include, but are not limited to: ethanol, methanol, and iso-propyl alcohol (or other alcohol or polar solvent; or non-polar solvent). In embodiments the liquid may be introduced via a porous roller 701, which may be termed a “doctor roller”, preferably at a controlled rate. An optical element 702 is provided; this may be a lens, prism or the like, for example fabricated from glass. In embodiments liquid remains in the capillary space between the optical element 702 and surplus liquid is discharged by progress of the recording medium (film) through the apparatus; optionally it may be reclaimed after use. As the drum rotates the film is exposed in a region 462. In the illustrated example the laser beams 703 define planes which intersect and interfere along a line which runs generally parallel to the axis of rotation on the surface of the cylinder.

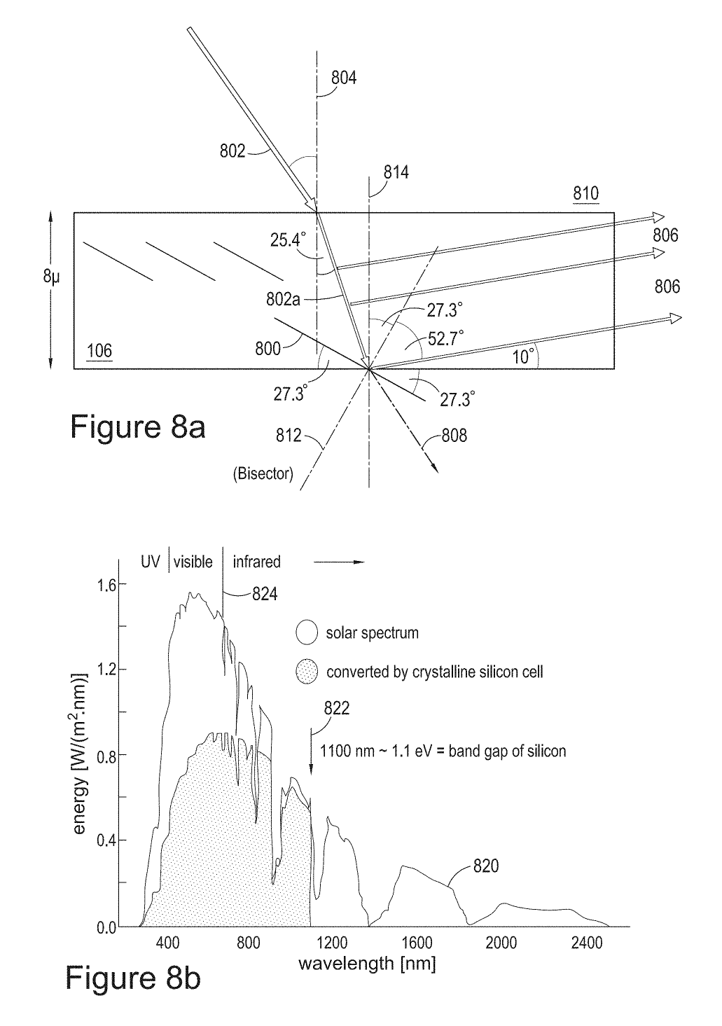

Referring now to FIG. 8a, this illustrates the determination of the angle of fringes 800 in a volume hologram 106 to achieve total internal reflection within a window pane for an example solar elevation. In London the sun's elevation at midday ranges between around 20° at the winter solstice and 60° at the summer solstice. For the sake of example we will consider a beam 802 from a solar elevation of 40° (the angle between ray 802 and the normal 804 to the surface of the hologram). It is desired, in this example to diffract ray 802 so that the rays 806 “reflected” from the fringes of the hologram are at an angle of 10° to the plane of the surface of the hologram as illustrated. Rays 806, comprise rays of a selected wavelength band or having a wavelength greater than a threshold wavelength; other light from beam 802 continues through the hologram and out as beam 808 to illuminate the far side of the window (in FIG. 8a the window pane is schematically illustrated by region 810).

Ray 802 is refracted to travel along an altered direction 802a within the hologram, in the illustrated example at an angle of 25.4° to normal 804. Line 812 defines a normal to fringe 800 and incoming ray 802a and reflected ray 806 make equal angles to this normal as illustrated each having an angle of 52.7° to normal 812. As can be seen from the figure, this in turn dictates that line 812, which defines a normal to the fringe, is at an angle of 27.3° to normal 814 to the surface of the hologram, and thus the fringes 800 themselves also have an angle of 27.3° to the plane of the hologram, that is to the film or tile surface. Thus when fabricating the volume hologram, for this example the fringes should be an angle of 27.3° with respect to the film surface. The skilled person will readily appreciate that the example given maybe modified for different solar elevations at different times/latitudes.

FIG. 8b illustrates an example target set of wavelengths for rays 806. Thus line 820 in FIG. 8b shows the solar spectrum and arrow 822 denotes a wavelength of 1100 nanometres which corresponds approximately to the 1.1 eV band gap of silicon—that is wavelengths shorter than 1100 nanometres can be converted to electricity by an inexpensive polycrystalline silicon solar photovoltaic cell. Line 824 notionally marks the start of the infrared region of the spectrum, here taken as light of a wavelength greater than 600 nanometres. Preferably, therefore, a volume hologram for the previously described window assembly has a fringe structure which is capable of “Edge-Directing” light of at least some wavelengths in the range 600 nanometres to 1100 nanometres although in this example there is no particular need to handle wavelengths greater than 1100 nanometres. The fringe structure described with reference to FIG. 8a could be fabricated using infrared film and interfering laser beams at appropriate angles, as previously described.

However in a preferred approach a transmission hologram is recorded using light of a shorter wavelength and then the fringes are rotated and to achieve an Edge-Directing fringe structure.

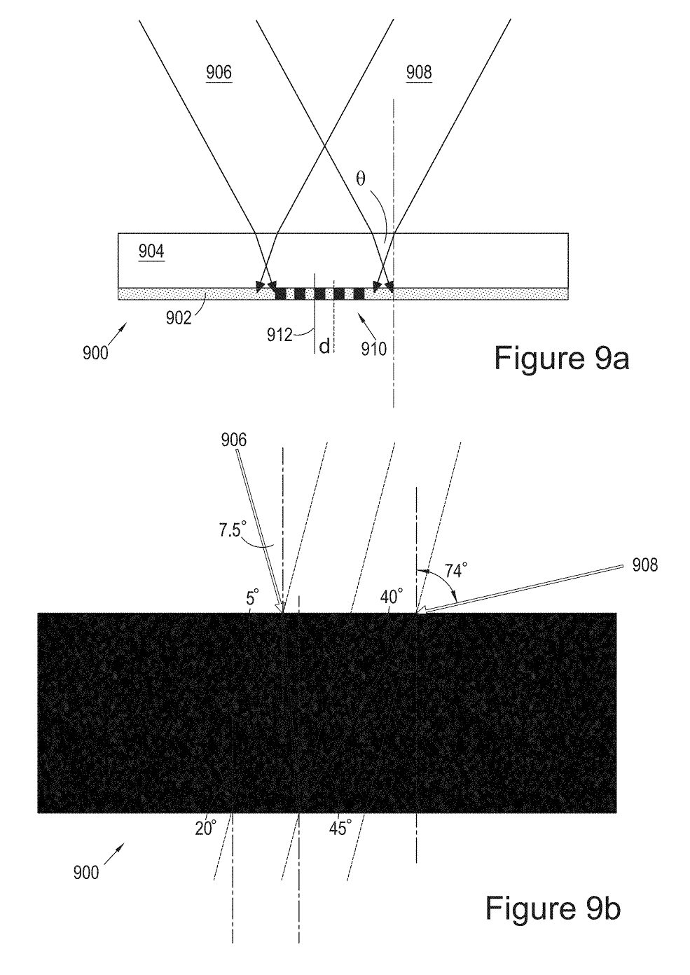

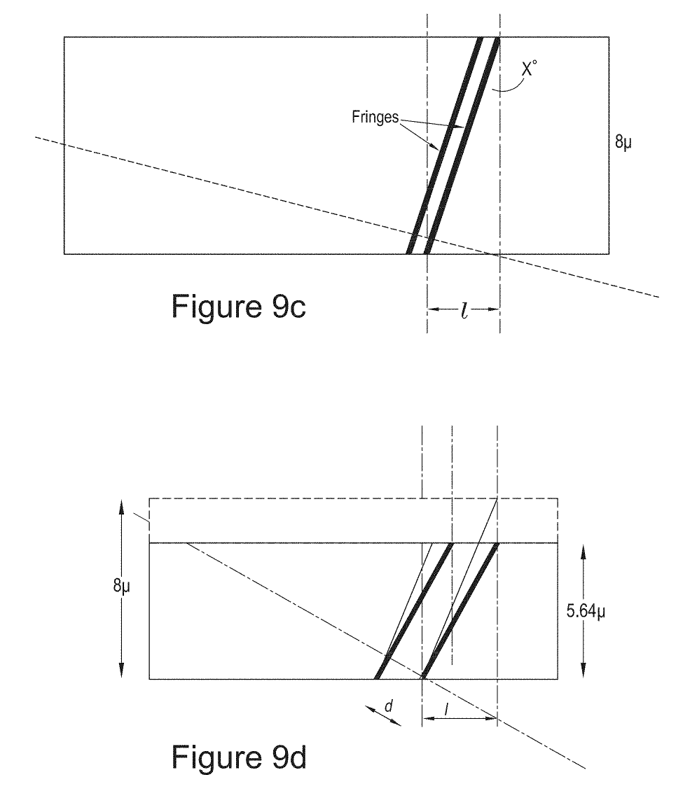

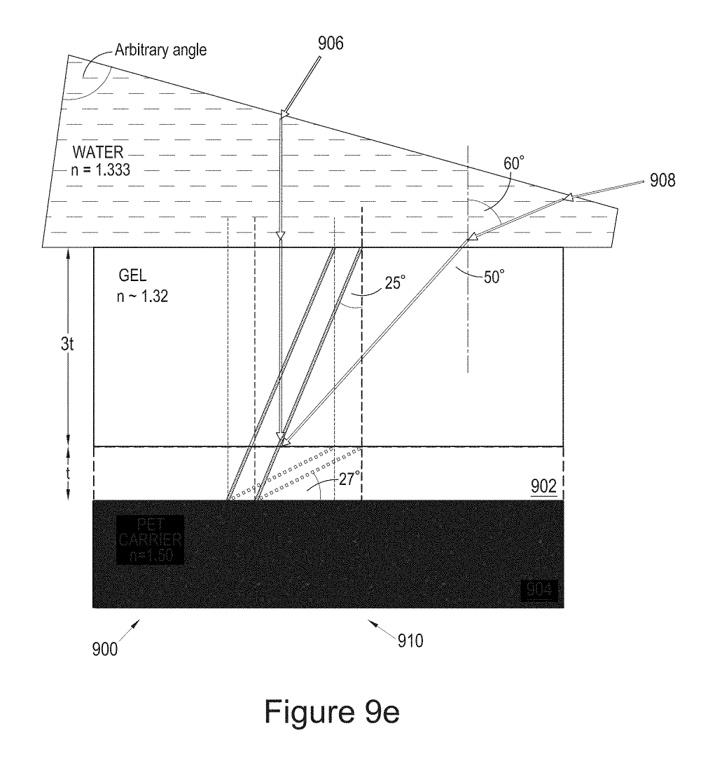

FIG. 9a shows the fabrication of a volume transmission hologram 900 comprising a layer of holographic recording medium 902 on a substrate 904. A pair of interfering laser beams at 906, 908, for example split from a single beam, are arranged to interfere over a region 910 of the recording medium 902, at an angle θ to one another to produce fringes with a spacing d. These are related to the wavelength λ by Bragg's Law:

λ/n=2d sin θ
where
λ=the wavelength of the laser light in air
n=the average refractive index of the recording layer
d=the fringe spacing
θ=half the angle between the recording beams

For thin holograms the refractive index term is frequently overlooked since the interference occurs effectively in air where refractive index is unity. In this case, we specifically consider volume holograms, where index differential is significant, and which are produced in silver halide emulsions in either wet or dry condition. Bjelkhagen ISBN 3-540-58619-9 Silver Halide Recording materials estimates for Kodak and Agfa Holotest films, emulsion prior to exposure with refractive index of the order of 1.50-1.60 and aqueous-swollen emulsion of the order of 1.32.

In the final volume hologram the fringe spacing should be appropriate to reflect red and infrared light—for example very roughly to reflect 800 nanometre light the fringe spacing should be approximately 0.4 μm; for example two 659 nanometre laser beams with angle 2θ between the beams (θ is half the free space angle), incident onto film as shown in FIG. 9a, will produce fringes in silver halide film with spacings indicated by the table below for different angles θ:

| θ | 10° | 20° | 30° |
|---|---|---|---|
| d (nm) | 1186 | 602 | 411 |

For two 1064 nanometre laser beams the corresponding table is:

| θ° | 10° | 20° | 30° |
|---|---|---|---|
| d (nm) | 1914 | 972 | 665 |

But for a laser of shorter wavelength such as 532 nm the fringe spacing is:

| θ° | 10° | 20° | 30° |
|---|---|---|---|
| d (nm) | 957 | 487 | 333 |

### FIRST EXAMPLE

Consider, for the sake of example, using a 659 nm laser, selecting a relative angle (2θ) of 45° for the two beams, corresponding to a fringe spacing of 487 nanometres. Now, rather than locating the film plane normal to a line bisecting the angle between the interfering beams, the film is tilted with respect to the interfering beams as shown in FIG. 9b.

By way of example we will select a tilt angle of X degrees, which tilts the fringes shown in FIG. 9a away from the vertical direction 912 by the same X degrees (FIG. 9c). In the simple arrangement of FIG. 9a the angle of X degrees may be limited by Snell's Law, for example to 42° assuming a refractive index for the recording material of 1.50 (unexposed photopolymer may have a lower refractive index). After film shrinkage (as illustrated in FIG. 9d), the fringes are at a desired target angle for edge-directing use.

As can be seen from FIG. 9d, the effect of shrinkage of the thickness of the film is to rotate the fringes and to alter their spacing (although their frequency at the surface of the hologram does not change). The relationship between the tilt angle of X degrees and the target angle is thus given by straightforward trigonometry—knowing distance I (FIG. 9c) and the final thickness of the film—the tangent of the final fringe angle is the ratio of these two values.

In one illustrative example the film is tilted so that X=20° and the film shrinks from an original thickness of 8 μm to 5.64 μm (30% shrinkage is readily achievable in practice). Referring to FIG. 9d, the calculation is then as follows:

tan 20°=I/8

### Therefore

I=2.91 μm

In shrinking the frequency in the surface plane does not change (FIG. 9d) so the fringe angle and spacing (in a direction perpendicular to the fringes) will both change. Therefore a new fringe angle X′ is given by:

tan X′=2.91/5.64

X′=27.3°

The original spacing of fringes with the example given above has d=487 nm

Therefore x·cos 20=487 where x is the surface spacing (which stays constant)

x=518 nm

and

d_{new}=518 cos 27.3

thus

d_{new}=460 nm.

The ratio of the spacings, d/d_{new} is given by the ratio of cos X′/cos X. Thus in a similar manner an original fringe spacing of, say, 466 nm would be reduced to 439 nm. The 460 nm (or 439 nm) grating spacing could (with an appropriate angle of incidence) have a useful reflectivity for infrared light at 814 nm nanometres for total internal reflection in the window pane, well suited for generating electricity using a silicon PV cell.

In the example of FIG. 9d the fringes end up at an angle of 27.4° to the normal to the surface of the film. In this example the fringes are thus not tilted at a sufficiently shallow angle to the surface to the film to direct the light as shown in FIG. 8a, through the thickness of a relatively thin film. Nonetheless, depending upon the geometry of the application, the optical properties of the recording material, the thickness of the film/layer through which the light is directed, and upon how glancing an angle is needed for total internal reflection within the film/layer, this approach may be sufficient.

### SECOND EXAMPLE

A second example is illustrated in FIG. 9e. In this example the fringes end up at an angle of around 27° to the surface of the film, as illustrated in FIG. 8a. In the example of FIG. 9e the beams are incident onto the film through a layer of liquid, as illustrated water, in contact with the film. The configuration of the tank which may be used to contain the liquid is arbitrary and may be designed to facilitate entry of light into the cell at a desired angle; or the water may be confined by capiliary action as previously described. In other approaches (for example as shown in FIG. 7e) a layer of solid (transparent) material such as glass may additionally or alternatively be employed, optionally with an index matching layer between the layer and the film. This allows the beams to enter the film at a shallower angle than would otherwise be the case; in the illustrated example one of the two beams enters from the normal position and the other enters from an angle of 50° in order to allow the resulting fringes to be formed at an angle which facilitates the ability for layer shrinkage to result in axial rotation of the microstructure.

This approach allows fringes to be formed with an initially shallower angle (to the surface of the film), and this can be further reduced by later shrinkage of the film. In the illustrated example the emulsion is initially swollen to 4 times its original thickness (4t), and afterwards shrunk back to its original thickness (t). This is readily achievable. Exposing the film through a liquid such as water facilitates such a procedure. This approach may be combined with that described previously with respect to FIGS. 4c and 7—that is the film may be run over a drum located in a liquid bath to provide a substantially continuous recording process (with stepwise flash or continuous exposure to the laser beams). Preferably the film is given sufficient time in the liquid to reach an equilibrium swollen thickness; in the case of continuous process this may be achieved with sufficiently long previous swelling prior to the recording stage.

As previously described there are many ways in which an emulsion layer may be shrunk. For example water-soluble material may be added in to the emulsion layer when this is coated on to the substrate. Then significant quantities of this material will leave the layer during subsequent aqueous processing. Additionally or alternatively the use of a solvent bleach process can contribute to the reduction of the thickness of the layer of recording medium by removal of silver from the layer during processing. This latter approach has the additional advantage of reducing “printout” that is residual sensitivity of the processed film product to light in particular ultraviolet light.

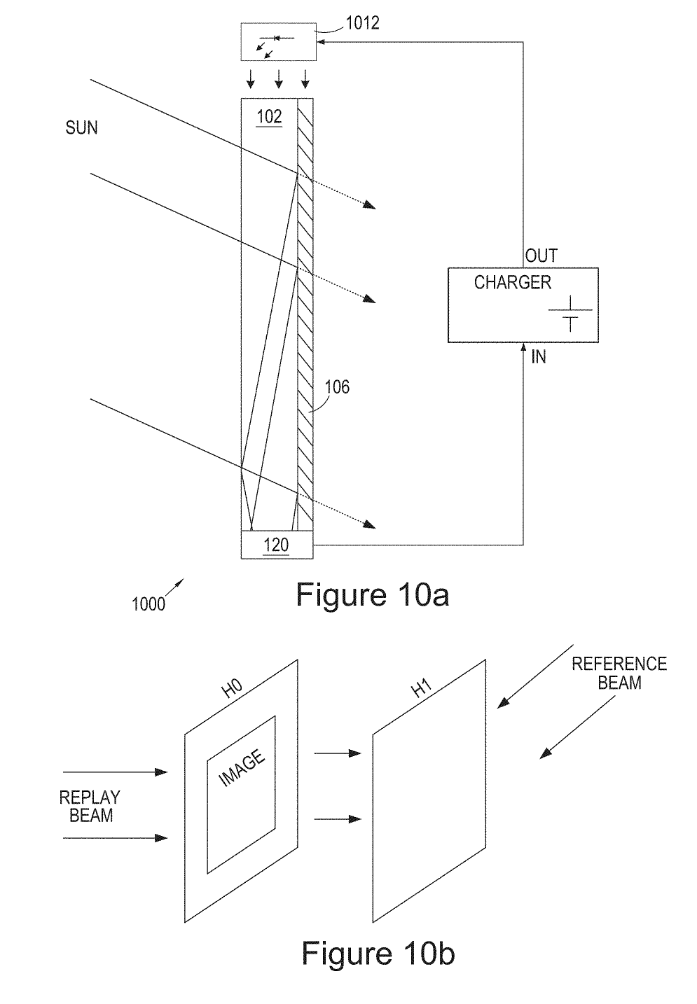

FIG. 10a illustrates a solar voltaic system 1000 of the type previously described in combination with an energy storage system 1010 system such as a charger and rechargeable battery, charged by PV element 120 and providing electrical energy to an illumination source 1012 such as one or more light omitting diodes. As illustrated, sunlight is captured at the bottom of the window pane 102 and the light source 1012 Edge-Illuminates the hologram 106 from the top of the window assembly. In this way the system 1000 is able to collect light during the hours of daylight and to provide an illuminated holographic image at other times. Preferably hologram 106 is Edge-Illuminated by a substantially collimated light which, in embodiments, may be substantially monochromatic. One advantage of hologram 106 being configured to receive sunlight from a range of angles is that an additional hologram for display purposes encoded into volume hologram 106 is visible over a range of angles. The skilled person will appreciate that power for light source 1012 need not be provided by PV element 120, although this is convenient.

Commercial holograms may be produced by recording the interference between one specular laser beam, whose orderly component rays are predominantly parallel, together with a diffuse beam whose rays issue from a diffuse surface in randomised directions. In this case, the former beam may be referred to as the “reference beam” and one considers the holographic recording to result from its modulation. Such a diffuse hologram, which is capable of high diffraction efficiency, as well as being a useful medium for display technology is capable of acting, in its own right, as an efficient HOE, whose numerical aperture is helpful in the present system.

The system of FIG. 10a employs a volume hologram of the type previously described for directing light to propagate within the thickness of a window pane, but in addition there is an image recorded in the volume hologram, preferably a three dimensional image, for replay when the hologram is suitably illuminated. FIG. 10b illustrates one method for fabricating such a hologram: The arrangement of FIG. 3d may be adapted to include an image, for example a diffuser located on or adjacent the H0 hologram, which is then recorded into the H1 hologram.

The skilled person will recognise that there are many potential applications for such systems. Furthermore in embodiments the use of window pane 102 in the system 1000 of FIG. 10a is optional—for example the hologram 106 (and its substrate) may itself direct sunlight towards PV element 120. Thus, for example, a film bearing the volume hologram could be used to provide signage, storing power from sunlight during the day and providing an illuminated screen at night. In one example application the rear or sides or windscreen of a container lorry could be provided with such signage. More generally one or more signals could be stored as images within the hologram, for example a red stop signal and/or orange turn signal which could then be lit by illuminating the hologram with light source 1012. In a little further application rather than reproducing an image such as a 3D image the hologram may instead be employed to produce specular or diffuse illumination of the interior or exterior region bounded by the window panel: in effect a window could be used as a source of light at night.

More generally, the sunlight itself may be employed to replay an image encoded in the volume hologram 106 even without Edge-Illumination 1012. This can be achieved by recording one or more images into the hologram rather than a simple grating structure; these one or more images maybe indexed by wavelength and/or angle. Further optionally where a plurality of different images is encoded dependent upon the innovation and/or azimuth angle of the sun, the position of the sun can be used to selectively display an image or image sequence. In this way a temporally animated image may be displayed, for example a display of local time based on the angular change in the direction of incident light on the surface of the hologram. This may be employed to provide an animated holographic image of a digital or analogue clock depicting the time based on the sun's position in the sky. Such an image may be a two dimensional or three dimensional image.

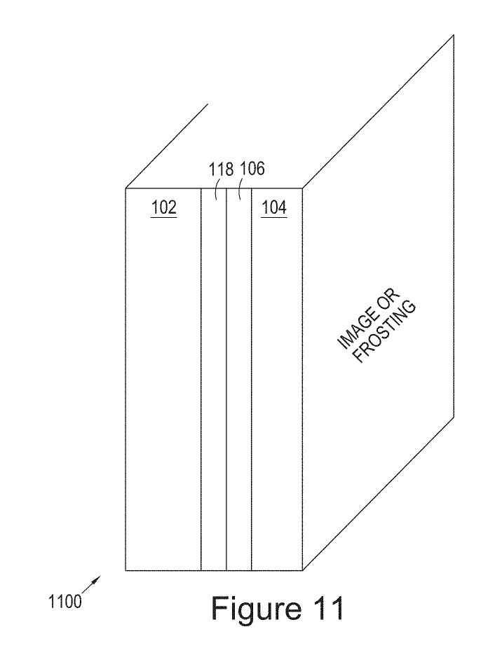

FIG. 11 illustrates a still further method encoding an image or other optical effect into the hologram: in this example the film or tile substrate 104 is modified to provide the image or optical effect without necessarily modifying the hologram 106. Thus, for example, a mirrored or frosted appearance may be provided on substrate 104, for example using a hard polyester substrate the surface of the substrate not bearing the hologram may be roughened to scatter light. More generally a toned, tinted, mirrored or frosted appearance may be provided by the substrate. This may be included as part of a window assembly either as a window pane or, for example, as part of a double glazing system.

It will be appreciated that there are many applications for this technology, including use in domestic, office or industrial buildings as well as, potentially, on vehicles. In principle embodiments of the techniques may also be employed on a window of a display, for example, of an electronic device. As previously described embodiments of the invention also have applications for signage and the like.

No doubt many other effective alternatives will occur to the skilled person and it will be understood that the invention is not limited to the described embodiments but encompasses modifications apparent to those skilled in the art lying within the spirit and scope of the claims appended hereto.

1. A window assembly comprising:
a window pane comprising a glass or plastic sheet; and
a layer of holographic recording medium attached to said glass or plastic sheet;
wherein said layer of holographic recording medium has recorded within the medium a volume hologram configured to direct light incident onto said glass or plastic sheet to propagate within a thickness of said glass or plastic sheet.

2. A window assembly as described in claim 1 wherein said volume hologram is configured to direct said incident light such that it propagates within said thickness of said sheet at an angle to a normal to said sheet equal to or greater than a critical angle of said glass or plastic sheet.

3. A window assembly as claimed in claim 1 wherein said volume hologram is configured to direct said incident light such that it propagates within said thickness of said sheet when said incident light has a wavelength longer than a threshold wavelength and to allow said incident light to pass through said thickness of said glass or plastic sheet when said incident light has a wavelength shorter than said threshold wavelength.

4. A window assembly as claimed in claim 1 wherein said volume hologram comprise fringes at a range of different angles such that light rays incident onto said glass or plastic sheet at a range of angles to a normal direction to said sheet are directed to propagate substantially parallel to one another.

5. A window assembly as claimed in claim 4 wherein said glass or plastic sheet defines two orthogonal axes each perpendicular to said normal direction, a first, vertical direction and a second, horizontal direction, and wherein said volume hologram comprises fringes at a range of different angles such that light rays incident onto said window and over a range of angles in each of said first and second directions are directed to propagate substantially parallel to one another

6. A window assembly as claimed in claim 4 wherein said volume hologram has a plurality of layers having fringes at a set of different angles, and wherein said volume hologram is indexed by wavelength such that at different angles of incidence of said light rays different wavelengths of said incident light are directed to propagate substantially parallel to one another.

7. A window assembly as claimed in claim 4 wherein said volume hologram has at least one layer having overlapping said fringes at said range of different angles.

8. A window assembly as claimed in claim 1 wherein said volume hologram is chirped such that a spacing of said fringes increases from a front to a rear surface of said hologram, or vice-versa.

9. A window assembly as claimed in claim 1 wherein said layer of holographic recording medium comprises a layer on a film substrate, and wherein said film substrate is glued to said glass or plastic sheet with said layer of holographic recording medium sandwiched between said sheet and said film substrate.

10. A window assembly as claimed in claim 9 wherein said film substrate bears an image separate to said volume hologram.

11. A window assembly as claimed in claim 1 wherein said volume hologram includes a hologram of an image of a spatial pattern such that said image is reproduced when said volume hologram or glass or plastic sheet is edge lit.

12. A window assembly as claimed in claim 1 further comprising a photovoltaic element mounted to receive light escaping from an edge of said glass or plastic sheet.

13. Holographic film for the window assembly of claim 1, comprising a film substrate bearing a layer of holographic recording medium, wherein said layer of holographic recording medium has recorded within the medium a volume hologram configured to direct light, incident onto the film or onto a glass or plastic sheet to which said film is attached, to propagate within a thickness of said film or said glass or plastic sheet, in particular wherein said volume hologram includes a hologram of an image of a spatial pattern such that said image in reproduced when said volume hologram or glass or plastic sheet is edge lit.

14. A method using the holographic film of claim 13 to convert a window pane comprising a glass or plastic sheet to a photovoltaic collector, the method comprising:
applying the holographic film of claim 13 to said glass or plastic sheet said that light incident on said sheet is directed to propagate within a thickness of said glass or plastic sheet; and
providing a photovoltaic element to receive light escaping from an edge of said glass or plastic sheet.

15-22. (canceled)

23. A method of providing solar power, the method comprising:
mounting a layer of holographic recording medium on a window pane comprising a glass or plastic sheet;
the method further comprising:
recording a volume hologram in said holographic recording medium;
directing sunlight falling on said window using said volume hologram to propagate within a thickness of said sheet; and
illuminating one or more photovoltaic elements with sunlight escaping from a lateral edge of said window to provide said solar power.

24. A method as claimed in claim 23 wherein said directing comprises selecting an angle of said propagating light to be equal to or greater than a critical angle of said glass or plastic sheet.

25. A method as claimed in claim 23 further comprising using said volume hologram to selectively divert longer wavelengths of said sunlight to illuminate said photovoltaic elements and transmitting shorter wavelengths in a substantially unchanged direction through said window, the method further comprising varying a fringe rotation of said volume hologram from top to bottom of said window to compensate for changes in solar elevation.

26. (canceled)

27. A method as claimed in claim 23 further comprising providing a plurality of sets of fringes within said volume hologram, one for each of a plurality of different solar azimuth values, wherein said sets of fringes constitute a volume hologram of plurality of replayed holograms, one for each azimuth value.

28. (canceled)

29. A method as claimed in claim 23 further comprising providing a plurality of sets of fringes within said volume hologram, wherein said sets of fringes are located in different layers of said volume hologram and indexed by different respective wavelengths of said sunlight.

30. A method as claimed in claim 23 further comprising chirping fringes of said volume hologram from front to back.

31-38 (canceled)
